(19) United States
(12) Patent Application Publication
(10) Pub. No.: US 2017/0316683 A1
(43) Pub. Date: Nov. 2, 2017

(54) Modular Sensor Systems

(71) Applicant: Ideation Systems LLC, Austin, TX (US)

(72) Inventors: Lukasz Leszek Pietrasik, Krotoszyn (PL); Adam Waldemar Golinski, Swidnik (PL); Filip Mateusz Kaklin, Edinburgh (GB); Ahmad Hani Zaatari, Austin, TX (US); Daniel James Yee, Austin, TX (US); Mohsen Nakhaeinejad, Austin, TX (US)

(73) Assignee: IDEATION SYSTEMS LLC, Austin, TX (US)

(21) Appl. No.: 15/431,584

(22) Filed: Feb. 13, 2017

Related U.S. Application Data
(63) Continuation-in-part of application No. 15/043,553, filed on Feb. 13, 2016.
(60) Provisional application No. 62/295,062, filed on Feb. 13, 2016.
(60) Provisional application No. 62/116,143, filed on Feb. 13, 2015.

(51) Int. Cl. G08C 19/10; G01D 21/02; G01D 11/24; G01D 18/00; G08C 19/22; G01R 19/00

(52) U.S. Cl. CPC G08C 19/10; G08C 19/22; G01R 19/0023; G01D 11/245; G01D 18/008; G01D 21/02

(57) ABSTRACT

In some embodiments, a sensor device can include a base module including a battery and including a transceiver configured to communicate with a computing device. The sensor device may further include one or more sensor modules configured to releasably couple to the base module. Each sensor module may be configured to receive power from the base module and to provide data to the base module

### CROSS-REFERENCE TO RELATED APPLICATION(S)

This application is a non-provisional of and claims priority to U.S. Provisional Patent Application No. 62/295,062 filed on Feb. 13, 2016 and entitled “Modular Sensor Systems”, which is incorporated herein. Further, the present application is a continuation-in-part of and claims priority to co-pending U.S. patent application Ser. No. 15/043,553 filed on Feb. 13, 2016 and entitled “Modular System Including Multiple Detachable Sensors”, which is incorporated herein by reference in its entirety

### FIELD

The present disclosure is generally related to sensor devices, and more particularly to a modular sensor system including multiple detachable sensors.

### BACKGROUND

Sensor devices for use in science classes and in institutes of higher education may include display interfaces as well as interfaces for copying bitmapped images to a storage device, such as a removable floppy disk, a thumb drive, or other storage device. Such sensor devices may include oscilloscopes, voltage and current meters, temperature sensors, other sensors, or any combination thereof. Unfortunately, such sensors are typically wired and may cost hundreds of dollars per device.

### SUMMARY

Embodiments of systems and methods are described below that include a base module which may include a power supply (such as a rechargeable battery), power management circuitry, and communication circuitry. In some embodiments, the base module may be inductively charged by a charging device. The base module may be configured to communicate with a computing device, such as a laptop, a smart phone, a desktop computer, another computing device, or any combination thereof through a first communication link, which may be wired or wireless. The base module may also include an interface configured to deliver power to and to communicate with one or more sensor modules, which may be configured to measure a parameter and to communicate measurement data to the base module. In some embodiments, the base module and the sensor modules may cooperate to provide a robust suite of easy-to-use sensors for use in a variety of testing environments, including university, test lab, and garage inventor settings.

In an embodiment, the sensor modules may be stackable and may be physically coupled to one another to form a multi-sensor device. The sensor modules may include POGO pins or other electrically connections. In some embodiments, they may be coupled inductively. Further, in some embodiments, the sensor modules may include magnets configured to secure the sensor modules to a structure or to each other. In some embodiments, the sensor modules may be coupled to a base module to form a device, which can be mounted to a structure, such as a cart or another device. In some embodiments, the sensors may be stacked and coupled to the base module to form a wearable device, such as a fitness band, a watch, another device, or any combination thereof.

In some embodiments, the robust suite may be configured to communicate data to a complementary software program that may be executed by a processor of the computing device. The complementary software program may capture and display data from the sensor modules. The complementary software program may provide a graphical interface including a plurality of user-selectable elements through which a user may interact with the data to label data points, to select between visualizations, to alter color selections, or any combination thereof. Data may be presented in tables, charts, graphs, or any combination thereof.

In some embodiments, a sensor device can include a base module including a battery and including a transceiver configured to communicate with a computing device. The sensor device may further include one or more sensor modules configured to releasably couple to the base module. Each sensor module may be configured to receive power from the base module and to provide data to the base module.

In other embodiments, an apparatus can include a sensor device including a base module including a transceiver, a sensor interface, and a power supply. The sensor device may further include one or more sensor modules including a first sensor module coupled to the sensor interface of the base module to provide sensor data. The base module may be configured to provide data related to the sensor data to a wireless communications link via the transceiver. The apparatus may further include a computing device configured to receive the data from the base module via the wireless communications link. The computing device can be configured to display one or more visualizations based on the data.

In still other embodiments, a sensor device can include a base module and one or more sensor modules configured to magnetically couple to the base module. The base module may include a battery and a transceiver configured to communicate with a computing device. Each sensor module may be configured to receive power from the base module and to provide data to the base module.

### BRIEF DESCRIPTION OF THE DRAWINGS

FIG. 1 is a block diagram of a system including a base module and at least one sensor module, in accordance with certain embodiments of the present disclosure.

FIG. 2 is a block diagram of a system including a base module and a plurality of sensor modules, in accordance with certain embodiments of the present disclosure.

FIG. 3A depicts a block diagram of a system including a base module and a plurality of sensor modules, in accordance with certain embodiments of the present disclosure.

FIG. 3B depicts a perspective view of a base module, in accordance with certain embodiments of the present disclosure.

FIG. 3C depicts a system including a base module and a sensor module, in accordance with certain embodiments of the present disclosure.

FIG. 4 depicts a pair of computing devices, represented as smart phone devices, each of which is displaying a different interface of a software application configured to communicate with the base module and with other systems, in accordance with certain embodiments of the present disclosure.

FIG. 5 depicts a computing device executing a lab application to provide an interface configured to allow configuration of a base module and one or more transducer modules, in accordance with certain embodiments of the present disclosure.

FIG. 6 depicts multiple sensors defining a modular sensor device and a smart phone computing device with sensor applications, in accordance with certain embodiments of the present disclosure.

FIG. 7 depicts multiple implementations of sensor devices including one or more sensor modules and a base module, in accordance with certain embodiments of the present disclosure.

FIG. 8 depicts a clip attachment implementation configured to releasably couple the sensor to the base module, in accordance with certain embodiments of the present disclosure.

FIG. 9 depicts a sensor system including an inductive charger, a base module and a stackable sensor configured to twist and lock to the base module, in accordance with certain embodiments of the present disclosure.

FIG. 10 depicts a liquid submersible sensor stack, in accordance with certain embodiments of the present disclosure.

FIG. 11 depicts a sensor system including a hinged ring for external attachment, in accordance with certain embodiments of the present disclosure.

FIG. 12 depicts multiple attachment mechanisms for coupling the sensors to each other and to the base module and for coupling the sensor stack to other devices, in accordance with certain embodiments of the present disclosure.

FIG. 13 depicts a sensor device including a fastener mount with a hook configured to engage the sensor device (base module and one or more sensors), in accordance with certain embodiments of the present disclosure.

FIGS. 14A and 14B depict an interconnecting block implementation of the sensor modules and the base module, in accordance with certain embodiments of the present disclosure.

FIG. 15 depicts an interconnecting block implementation of the sensor modules and the base module, in accordance with certain embodiments of the present disclosure.

FIG. 16 depicts a system including a module and an inductive charging base, in accordance with certain embodiments of the present disclosure.

FIG. 17 depicts a three-dimensional representation of the interconnected block configurations of FIGS. 14A-15, in accordance with certain embodiments of the present disclosure.

FIG. 18 depicts a three-dimensional representation of the interconnected block configurations of FIG. 17, in accordance with certain embodiments of the present disclosure

FIG. 19 depicts a sensor system including a stacked sensor device coupled to a cart, in accordance with certain embodiments of the present disclosure.

FIGS. 20A and 20B depict a stacked sensor device and different types of electrical connections, in accordance with certain embodiments of the present disclosure.

FIGS. 21A-21D depict different configurations of sensor modules and one or more base modules, in accordance with certain embodiments of the present disclosure.

FIG. 22 depicts a short-range wireless pairing and multi-sensor pairing of a smart phone to a plurality of sensor devices, in accordance with certain embodiments of the present disclosure.

FIG. 23 depicts distance/proximity pairing of a smart phone to one or more sensor devices, in accordance with certain embodiments of the present disclosure.

FIG. 24 depicts touch pairing of a smart phone to a sensor device, in accordance with certain embodiments of the present disclosure.

FIG. 25 depicts a laptop computer including a display showing an interface to build a 3D experiment and to order pre-printed (already prepared) experiments, in accordance with certain embodiments of the present disclosure.

FIG. 26 depicts a smart phone including a display showing an interface to build a 3D experiment and to order pre-printed (already prepared) experiments, in accordance with certain embodiments of the present disclosure.

FIG. 27 depicts a smart phone and sensor devices configured to interface directly to the smart phone, in accordance with certain embodiments of the present disclosure.

FIG. 28 depicts a smart phone including an interface depicting an open inquiry mode, in accordance with certain embodiments of the present disclosure.

FIG. 29 depicts a smart phone including an interface depicting a teacher mode, in accordance with certain embodiments of the present disclosure.

FIG. 30 depicts a smart phone including an interface depicting a student mode, in accordance with certain embodiments of the present disclosure.

FIGS. 31A and 31B depict a sensor device with a display and a smart phone displaying a data visualization, in accordance with certain embodiments of the present disclosure.

FIGS. 32A-32D depicts multiple possible attachment implementations for coupling a sensor device to a member, in accordance with certain embodiments of the present disclosure.

FIGS. 33A and 33B depict attachment implementations for coupling a sensor device to a substrate, in accordance with certain embodiments of the present disclosure.

FIG. 34 depicts a rubber ball implementation including a rubber ball housing configured to secure a sensor device, in accordance with certain embodiments of the present disclosure.

FIG. 35 depicts a sensor device configured to swing like a pendulum, in accordance with certain embodiments of the present disclosure.

FIG. 36 depicts a sensor device configured to secure a weight on a hook and to determine a pull force, in accordance with certain embodiments of the present disclosure.

FIG. 37 depicts a system including a four-wheel cart having a sensor device mounted thereon, in accordance with certain embodiments of the present disclosure.

FIGS. 38A and 38B depict carrying mechanisms configured to carry the sensor device, in accordance with certain embodiments of the present disclosure.

FIG. 39 depicts a sensor device including a protective ring or tire of various materials, in accordance with certain embodiments of the present disclosure.

FIG. 40 depicts a sensor device configured to couple to an interlocking plastic building block (such as a LEGO® building block), in accordance with certain embodiments of the present disclosure.

FIG. 41 depicts a motion-based or collision-based energy harvesting sensor device, in accordance with certain embodiments of the present disclosure.

FIG. 42 depicts a sensor device including a memory card for data storage, in accordance with certain embodiments of the present disclosure.

FIG. 43 depicts a sensor device including a surface configured to allow for personalization, to display an identifier, or both, in accordance with certain embodiments of the present disclosure.

FIG. 44 depicts a smart phone configured to communicate with a sensor, a motor, or both, in accordance with certain embodiments of the present disclosure.

FIG. 45 depicts sensor devices including light-emitting diodes (LEDs), in accordance with certain embodiments of the present disclosure.

FIG. 46 depicts a smart phone and sensor devices configured to upload and store data to a cloud-based server device, in accordance with certain embodiments of the present disclosure.

FIG. 47 depicts a portion of an example collision experiment using a sensor device, in accordance with certain embodiments of the present disclosure.

FIG. 48 depicts a portion of an example pendulum experiment using a sensor device, in accordance with certain embodiments of the present disclosure.

FIG. 49 depicts a portion of an example revolution experiment using a sensor device, in accordance with certain embodiments of the present disclosure.

FIG. 50 depicts a portion of an example slope experiment using a sensor device, in accordance with certain embodiments of the present disclosure.

FIGS. 51A and 51B depict a base module and at least one sensor module that can be used in an experiment involving tension and optionally pendulum motion, in accordance with certain embodiments of the present disclosure.

FIG. 52 depicts a base module and a plurality of sensor modules, in accordance with certain embodiments of the present disclosure.

FIG. 53 depicts a base module and a plurality of sensor modules having a twist and lock attachment feature, in accordance with certain embodiments of the present disclosure.

FIG. 54 depicts a base module and a plurality of sensor modules having a twist and lock attachment feature, in accordance with certain embodiments of the present disclosure.

In the following discussion, the same reference numbers are used in the various embodiments to indicate the same or similar elements.

### DETAILED DESCRIPTION OF ILLUSTRATIVE EMBODIMENTS

In the following detailed description of embodiments, reference is made to the accompanying drawings which form a part hereof, and which are shown by way of illustrations. It is to be understood that features of various described embodiments may be combined, other embodiments may be utilized, and structural changes may be made without departing from the scope of the present disclosure. It is also to be understood that features of the various embodiments and examples herein can be combined, exchanged, or removed without departing from the scope of the present disclosure.

In accordance with various embodiments, the methods and functions described herein may be implemented as one or more software programs running on a computing device, such as a tablet computer, smartphone, personal computer, server, or any other computing device. Dedicated hardware implementations including, but not limited to, application specific integrated circuits, programmable logic arrays, and other hardware devices can likewise be constructed to implement the methods and functions described herein. Further, the methods described herein may be implemented as a device, such as a computer readable storage device or memory device, including instructions that, when executed, cause a processor to perform the methods. Examples of such storage devices can include non-volatile storage devices, such as flash memories, hard disc drives, compact discs (CDs), other non-volatile memory, or any combination thereof.

Embodiments of systems are described below that can include a base module configured to communicate with a computing device, such as a smartphone, a tablet computer, a laptop computer, another computing device, or any combination thereof. The base module may include a controller, an interface configured to communicatively couple to at least one sensor module, and a pair of magnets configured to secure the sensor module to the base module. Further, the magnets may cooperate with corresponding magnets of the sensor module to ensure a consistent (and correct by design) alignment of the interface of the base module to a corresponding interface of the sensor module.

In some embodiments, the base module may also include one or more sensors, such as a plurality of motion sensors. In one possible embodiment, the base module may include one or more accelerometers, one or more magnetometers, one or more inclinometers, one or more other movement sensors, an inertial measurement unit circuit, or any combination thereof. In some embodiments, the base module may communicate measurement data to the computing device through a wired or wireless communication link.

The base module may communicate power and data to each sensor module. The sensor modules may be coupled to one another. An N-th sensor module may communicate with the base module through intervening sensor modules. In some embodiments, each sensor module may be configured to measure one or more parameters, such as temperature, pressure, acceleration, impact force, and so on. Each sensor may communicate measurement data to the base module, which may relay the data to the computing device.

In the following discussion, reference is made to sensor modules and base modules. However, the implementations described below may be used with transducers of any type, including sensor transducers, motors, actuators, other devices, or any combination thereof.

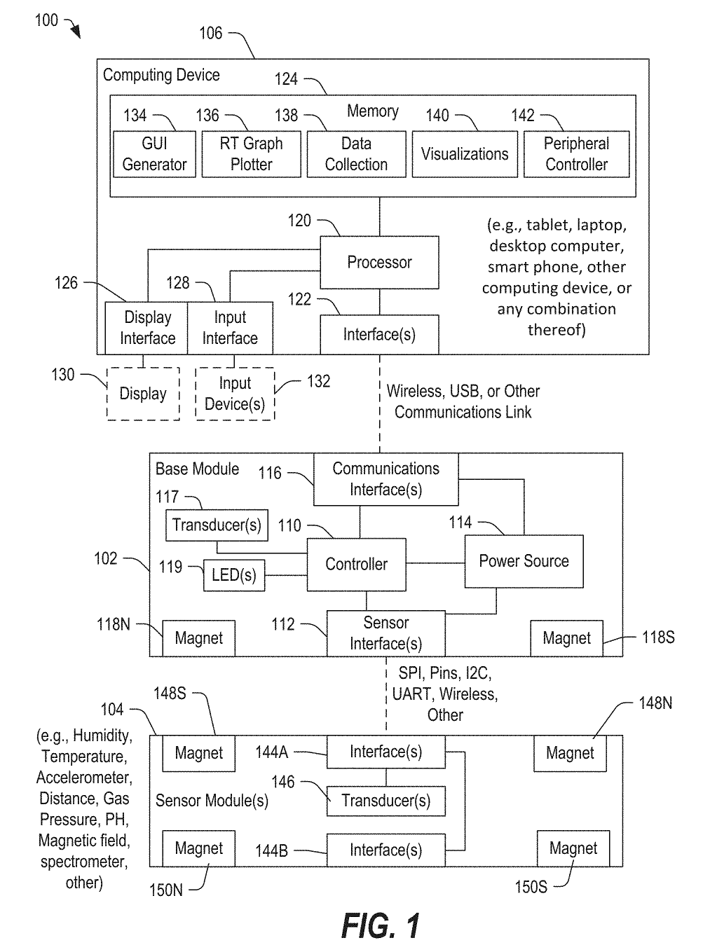

FIG. 1 is a block diagram of a system 100 including a base module 102 and at least one sensor module 104, in accordance with certain embodiments of the present disclosure. The base module 102 may be configured to communicate with one or more sensor modules 104 and may be configured to communicate with a computing device 106. In some embodiments, the computing device 106 may be a tablet computer, a laptop, a desktop computer, a smart phone, another computing device, or any combination thereof.

The base module 102 may include a controller 110 coupled to a sensor interface circuit 112, which may include one or more sensor interfaces configured to communicate with one or more sensor modules 104. The sensor interface circuit 112 may include a serial peripheral interface (SPI), pins, an inter-integrated circuit (I²C) interface, a universal asynchronous receiver/transmitter (UART) interface, a wireless interface (e.g., Bluetooth®, IEEE 302.11x, or another wireless interface), a universal serial bus (USB) interface, another communications interface, or any combination thereof. The base module 102 may further include a communications interface circuit 116 coupled to the controller 110 and configured to communicate with the computing device 106. The communications interface circuit 116 may include a wireless transceiver, a USB interface, a memory card or flash card interface (such as an interface for a secure digital (SD) card, a mini-SD card, a compact flash memory, a memory stick, a smart media card, another memory device, or any combination thereof), a livewire connection, another type interface, or any combination thereof. In some embodiments, the base module 102 may also include a power source 114. In an alternative embodiment, the base module 102 may receive power from the computing device 106, such as from a universal serial bus (USB) connection. In some embodiments, the power source 114 may include a power supply circuit configured to receive power from an external power supply, such as a plug or outlet. In some embodiments, the power source 114 may include a rechargeable battery 114. The controller 110 may control the communications interface 116, the sensor interface 112, and the power source 114. In some embodiments, the controller 110 may control recharge operations with respect to the power source 114. The power source 114 may also include a power management unit or other recharge interface, such as an inductive recharge interface, through which the power source may be recharged. Further, in some embodiments, the base module 102 may include a plurality of sensors or transducers 117, such as motion sensors, coupled the controller 110. Such sensors can include one or more accelerometers, one or more magnetometers, one or more inclinometers, one or more other movement sensors, an inertial measurement unit circuit, or any combination thereof. Further, the base module 102 may include one or more light-emitting diodes (LEDs) 119, which may provide an indication that the base module 104 is turned on, communicatively coupled to a computing device, connected to one or more sensor devices, or any combination thereof. The base module 102 may be configured to communicate with and sometimes couple to one or more detachable sensor modules 104. In some embodiments, the base module 102 may include a plurality of magnets 118. The magnets 118 may be arranged to provide a first and a second polarity at a surface of the base module 102, such as the magnet 118N and the magnet 118S, which orientations may be used to control the orientation of an attached sensor module 104.

The sensor modules 104 can include sensor circuitry configured to provide a variety of sensor functions, including gyroscopes, accelerometers, speed sensors, humidity sensors, temperature sensors, accelerometers, inclinometers, altimeters, gas pressure sensors, distance (e.g., range) sensors, acidity/basicity (PH) sensors, magnetic field sensors, spectrometers, other sensors, or any combination thereof. Each sensor module 104 may include one or more transducers 146 configured to convert particular parameters (e.g., force, temperature, impact, etc.) into electrical signals. Further, the sensor modules 104 may include an interface 144 coupled to the transducer 146. The interface 144 may be configured to couple to or otherwise communicate with the sensor interface 112 of the base module 102. In some embodiments, the sensor module 104 may include a rechargeable battery or capacitor, which may be charged when the sensor module 104 is coupled to the base module 102. In some embodiments, the sensor module 104 may be powered by the base module 102 via a power bus.

The sensor module 104 may further include a plurality of interfaces 144, such as a first interface 144A and a second interface 144B on opposite sides of the sensor module 104. In other embodiments, the sensor module 104 may include additional interfaces on adjacent sides. In the illustrated example, the sensor module 104 may include a first plurality of magnets 148 on a first side configured to mate with the base module and a second plurality of magnets 150 on a second side, which magnets 150 may be configured to couple to corresponding magnets 148 of another sensor module 102. In the illustrated example, the sensor module 104 includes a first magnet 148S configured to mate with magnet 118N and a second magnet 148N configured to mate with magnet 118S.

The computing device 106 may include a processor circuit 120, which may include one or more processors. The computing device 106 may further include an interface 122, which may be configured to communicate with the base module 102 via a communications link, which can be wired or wireless. Additionally, the computing device 106 may include a memory device 124, which may be coupled to the processor 120. The computing device 106 can also include a display interface 126 and an input interface 128, which may be coupled to the processor circuit 120. In some embodiments of the computing device 106, such as a smart phone or tablet computer implementation, the display interface 126 and the input interface 128 may form a touchscreen interface. In some embodiments, such as a desktop computer or laptop computer implementation, the display interface 126 may couple to a display 130 and the input interface 126 may couple to one or more input devices 132, such as a keyboard, a mouse, a track pad, or other input device.

The memory 124 may store data and may store instructions that, when executed, can cause the processor 120 to perform various functions and methods. In some embodiments, the memory 124 may include a graphical user interface module 134 that, when executed, may cause the processor 120 to generate an interface and to provide the interface to the display interface 126 for presentation via an integrated display, a touchscreen or via the display 130. The interface may include data corresponding to electrical signals generated by the sensor module 104 and communicated to the base module 102, which may have communicated the data (and optionally other data, such as a time stamp) to the computing device 106. The interface may also include one or more user-selectable elements, such as pull down menus, text inputs, buttons, links, other selectable elements, or any combination thereof. In some embodiments, at least one of the menus, links, or buttons may be accessible by a user to select a visualization of the data from a plurality of possible visualizations, such as selecting between a table, a bar graph, a line graph, another visualization, or any combination thereof and may include a text input configured to enable the user to label the axes and optionally the displayed graph. The interface may also include a menu, a link, a button, or another selectable option accessible by a user to alter one or more parameters, such as color, font, style or other parameters.

The memory 124 may further include a real time (RT) graph plotter 136 that, when executed, may cause the processor 120 to plot data values in a selected graph format for inclusion within the interface. The memory 124 may also include a data collection module 138 that, when executed, may cause the processor 120 to capture the data from the sensor module 104 and to store the data. In some embodiments, the collection module 138 may store the data in a table, a database, or another format. In some embodiments, the memory 124 may include a visualizations module 140 that may include a plurality of visualizations for representing data, including graphs, maps, images, tables, other visualizations, or any combination thereof. The processor 120 may access one or more of the visualizations 140 in conjunction with the GUI generator 134 and the RT graph plotter 136 to present the data from the sensor module 104 within a selected visualization. The memory 124 may also include a peripheral controller 142 that, when executed, may cause the processor 120 to control the sensor module 104, the base station 102, or any combination thereof.

In some embodiments, the computing device 106 may communicate with or be replaced by a cloud-based computing system, and the communications interface 116 of the base module 102 may be configured to communicate with the cloud-based system via Ethernet, WiFi, cellular telephone, digital telephone, another communications medium, or any combination thereof. In other embodiments, the base module 102 may be integrated with the computing device 106, such that the sensor modules 104 may communicate directly with the computing device 106. Other embodiments are also possible.

In some embodiments, the sensor module 104 may attach to the base module 102 to form a sensor apparatus. The base module 102 may include an attachment mechanism configured to mate with a corresponding attachment mechanism of the sensor module 104 to secure the sensor module 104. Further, the base module 102 may include an electrical interface configured to mate with a corresponding electrical interface of the sensor module 104 to exchange power, data, instructions, or any combination thereof. The magnets 118 may cooperate with the magnets 148 to ensure a correct orientation of the sensor module 104 relative to the base module 102 so that the electrical interconnections are correct by design. Further, in some embodiments, the magnets 150 may couple to corresponding magnets 148 of a next sensor module 140 to ensure a consistent, and correct electrical interconnection. In addition to ensuring a correct electrical interconnection, the magnets cooperate to secure the sensor modules 104 to one another and to secure the sensor module 104 to the base module 102. Other embodiments are also possible.

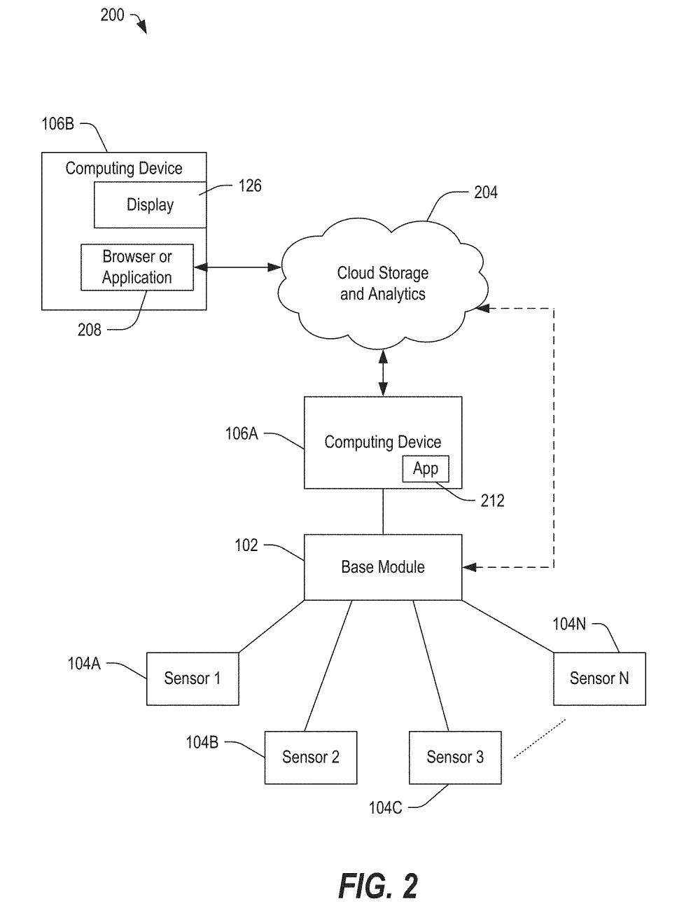

FIG. 2 is a block diagram of a system 200 including a base module 102 coupled to a plurality of sensor modules 104A, 104B, 104C, and 104N, in accordance with certain embodiments of the present disclosure. The system 200 may include a computing device 106 configured to communicate with the base module 102 through a network, via a cloud storage and analytics system 204, or any combination thereof. The base module 102 may communicate with one or more sensors 104. Sensor modules 104 may be configured to provide electrical signals proportional to one or more parameters to be measured and to communicate the electrical signals (or data related thereto) to the base module 102. In some embodiments, the sensor modules 104 may measure the one or more parameters, such as the parameters listed with respect to the sensor module 104 in FIG. 1. The sensor modules 104 may measure a plurality of parameters substantially simultaneously. Further, the sensor modules 104 may be selectively changed and new sensor modules 104 added, depending on the implementation.

In some embodiments, the computing device 106 may include an application 212, which may be executed by the processor 120 and which may include the GUI generator 134, the real-time graph plotter 136, the data collection module 138, the visualizations 140, and the peripheral controller 142 described above with respect to FIG. 1. Further, the application 212 may be configured to communicate at least some portion of the data to the display interface 126, to a remote device via a network, to the cloud storage and analytics system 204, or any combination thereof.

While only four sensor modules 104 are shown, the base module 102 may be configured to communicate with more than four sensor modules 104 and to provide data from the sensor modules 104 to the computing device 106. Thus, the base module 102 may function, at least in part, as an adapter configured to facilitate substantially simultaneous communication between multiple sensor modules 104 and the computing device 106.

In some embodiments, in lieu of or in addition to the processing performed by computing device 106, a system may be provided that can include a memory and one or more processors accessible via a network, such as a cloud-based computing system (which may include one or more computing devices configured to share processing of data). In an example, the application 212 of the computing device 106A may be configured to provide received data to the cloud storage and analytics 204 for further processing. The processed data (and the raw measurement data) may be accessed by the computing device 106A or the computing device 106B, for example, using an Internet browser or another application 208 (or using an instance of the application 212, depending on the implementation). Other embodiments are also possible.

In some embodiments, the analytics, visualizations, and processing of the data may be performed by the cloud storage and analytics 204. Further, the resulting processed data and visualizations may be accessed by a user via the browser or other application 208 at computing device 106B, via the application 212 at computing device 106A, via another computing device 106, or any combination thereof.

In the illustrated examples, the computing device 106A can communicate with the base module 102, which may be configured to communicate with a plurality of sensor modules 104. In one embodiment, the computing device 106A may be utilized by a student to confirm the connectivity of the various sensors (transducers), to configure the system, to review data collected by the sensor modules 104 (including selecting one or more visualizations for displaying the data), and to prepare a laboratory report based on the data. In another embodiment, the computing device 106A may be utilized by a teacher to configure a curriculum or to select one or more pre-defined lessons. Other embodiments are also possible.

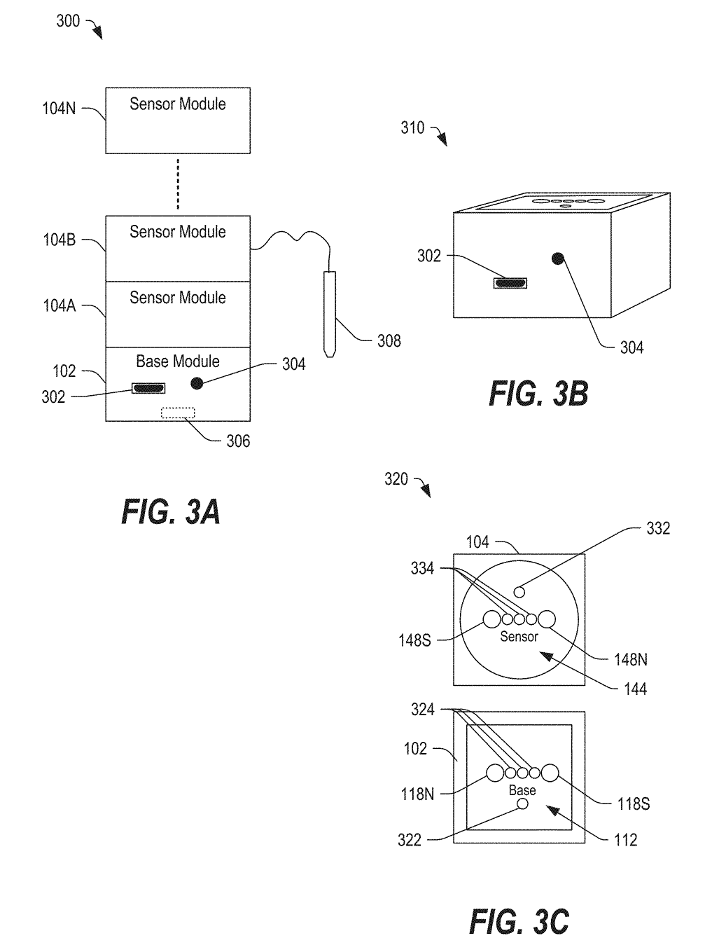

FIG. 3A depicts a block diagram of a system 300 including a base module 102 and a plurality of sensor modules 104, in accordance with certain embodiments of the present disclosure. In the illustrated example, the base module 102 may include a micro Universal Serial Bus (USB) port 302, which can be used to couple the base module 102 to a USB or other port of a computing device 106 or to a recharger. In some embodiments, the base module 102 may communicate data to the computing device via a USB cable coupled to the micro USB port 302. Further, the base module 102 may include a button 304, which may be accessed by a user to activate the base module 102 and to synchronize the base module 102 to a wireless communication link of the computing device 106, such as a Bluetooth® communications link. In some embodiments, the base module 102 may receive instructions that can be executed by the controller of the base module 102 through one of the wired and the wireless communications link. The base module 102 may also include one or more light-emitting diodes 306, which may indicate that the base module 102 has been activated, to indicate that the base module 102 is communicatively linked to a computing device 106, and so on. In some embodiments, one or more LEDs 106 may be included, which LEDs 106 may have different colors, where the illuminated color or colors can communicate specific information.

Further, the base module 102 may communicate with each of a plurality of sensor modules 104A, 104B, and 104N through a plurality of electrical interconnection pads. Additionally, the base module 102 may be physically secured to the sensor module 104A using magnets and may be electrically interconnected by corresponding electrical pads on the base module 102 and on a first side of the sensor module 104A. The sensor module 104A may be coupled to the sensor module 104B by magnets configured to physically secure the connection and to electrically secure the connection by corresponding electrical pads on a second side of the sensor module 104A and on a first side of the sensor module 104B. Moreover, additional sensor modules 104 may be stacked onto one another to form a sensor apparatus.

In the illustrated example, the sensor module 104B includes a probe 308, which may be a temperature probe, an optical probe, or another type of probe. In some embodiments, the sensor 104B can include one or more probes, which can be used to measure a variety of parameters. Other embodiments are also possible.

FIG. 3B depicts a perspective view 310 of a base module 102, in accordance with certain embodiments of the present disclosure. The base module 102 is depicted as a having a rectangular prism shape; however, other shapes are also possible, such as a cylindrical shape, a cubic shape, and so on. In the illustrated example, the micro USB port 302 and button are shown on a first phase, and magnetic and electrical interconnections are shown on a top face (which are also shown in FIG. 3C). Additional interfaces may also be included on one or more of the faces of the base module 102. Such additional interfaces can include, for example, a memory port configured to receive a flash memory device or another type of connector. Other embodiments are also possible.

FIG. 3C depicts a system 320 including a base module 102 and a sensor module 104, in accordance with certain embodiments of the present disclosure. In this example, the base module 102 includes magnets 118 and a communications interface 112 including contacts 322 and 324. In this example, the contacts 322 and 324 may include a pair of power contacts and a pair of communication contacts. Other embodiments are also possible.

Sensor module 104 may include magnets 148 (and 150 on an opposing side) and a communications interface 144. The communications interface 144 includes contacts 332 and 334 In this example, the contacts 332 and 334 may include a pair of power contacts and a pair of communication contacts. Other embodiments are also possible.

In certain embodiments, the polarities of the magnets 118 and 148 cooperate to ensure correct alignment of the communications interface 144 to the communications interface 112. Similarly, polarities of magnets 150 (shown in FIG. 1) and corresponding magnets 148 of a next sensor module 104 ensure correct alignment of the corresponding communications interfaces 144. Other embodiments are also possible.

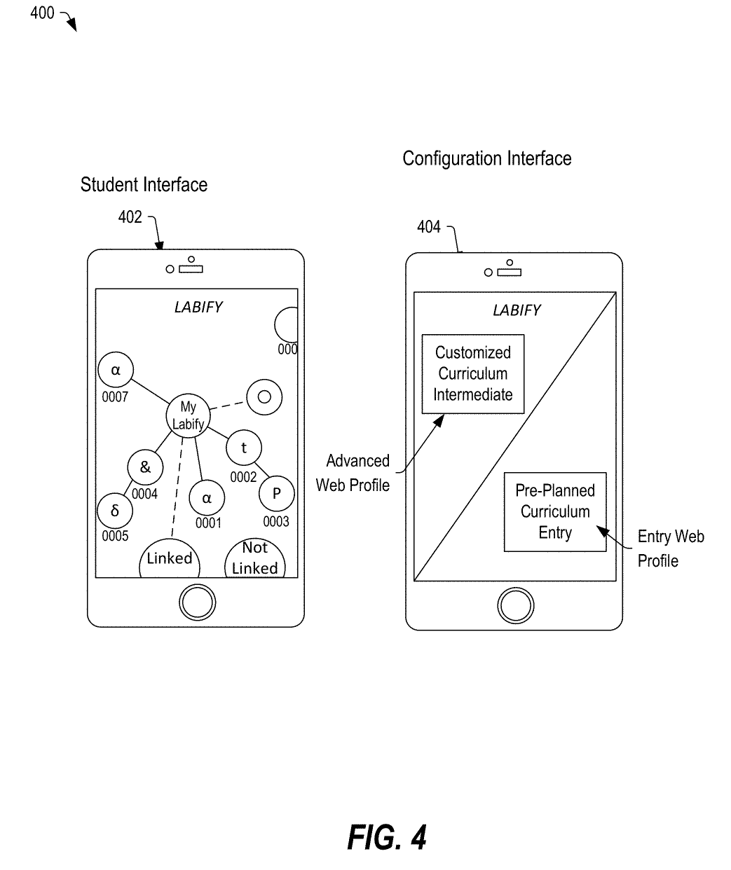

FIG. 4 depicts a system 400 including a pair of computing devices 402 and 404, represented as smart phone devices, each of which is displaying a different interface of a software application configured to communicate with the base module 102 and with other systems, in accordance with certain embodiments of the present disclosure. Though two smart phones are shown, it should be appreciated that the student interface (depicted on the touchscreen of the computing device 402) and the configuration interface (depicted on the touchscreen of the computing device 404) nay be accessible through the same computing device using different logins, for example. It should be understood that the computing devices 402 and 404 are examples of the computing device 106 in FIGS. 1 and 2.

In some embodiments, the student interface on the computing device 402 may be accessible by a user to configure various sensors, to verify that the sensors are linked to the base module, and so on. In some examples, the student interface may allow the user to specify a system of measurement, such as metric, Celsius, and so on.

The configuration interface on the computing device 404 may be accessed, for example, by a teacher to download and optionally modify an existing experiment or to create a new experiment. The selected experiment may then be pushed to the student devices for a curriculum. Other embodiments are also possible.

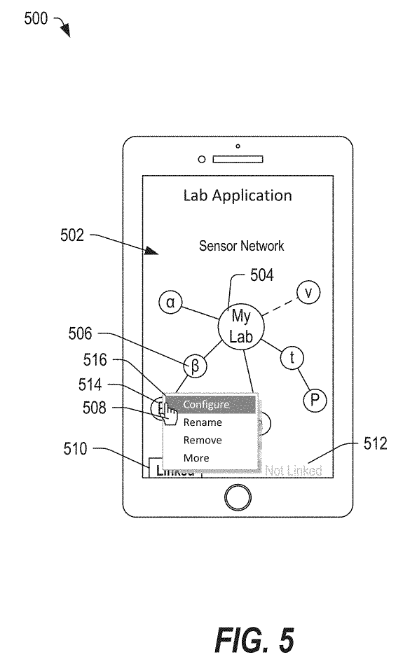

FIG. 5 depicts a computing device 500 executing a lab application to provide an interface configured to allow configuration of a base module and one or more transducer modules, in accordance with certain embodiments of the present disclosure. The computing device 500 may be an example of the computing device 106 in FIGS. 1 and 2. The computing device 500 includes a touchscreen interface 502, which may present an interactive interface through which a user may verify a sensor setup and configure a system that includes a base module and multiple sensors. In the illustrated example, the interface includes a plurality of objects, each of which represents a component of the sensor system.

The interface includes a first object (labeled “My Lab”) 504, which may represent a base module. A plurality of transducers, such as sensors, actuators, and the like, may be represented by objects, such as the object 506, which may be a transducer, such as a temperature sensor, an accelerometer, a pressure sensor, a velocity sensor, an environmental sensor, a tension sensor, a compression sensor, a current sensor, a voltage sensor, a another sensor, or any combination thereof.

The interface further includes selectable options to configure a particular sensor. In the illustrated example, a user may touch one of the sensors (as indicated by the pointer 508). In some embodiments, hovering over or touching an object within the interface, such as the object 514, may cause the interface to display an indicator about whether the device is linked or not linked to the base module 504. In this example, the indicator 510 indicates that the sensor 514 is linked, while the “Not Linked” indicator 512 is greyed out. In another embodiment, the indicator may be a lock or a solid line, while a dashed line may indicate that configuration is needed.

In the illustrated example, a user may right click or option click the sensor 514 to open a configuration menu 516. The configuration menu 516 may allow a user to configure various parameters of the sensor 514, such as defining a range, identifying a unit of measure, and so on. Further, the configuration menu 516 may allow the user to rename the sensor, remove the sensor from the configuration, or access more options. Any number of configuration options may be provided, and the user may access a menu associated with each of the sensors to configure the sensors for a particular experiment. Other embodiments are also possible.

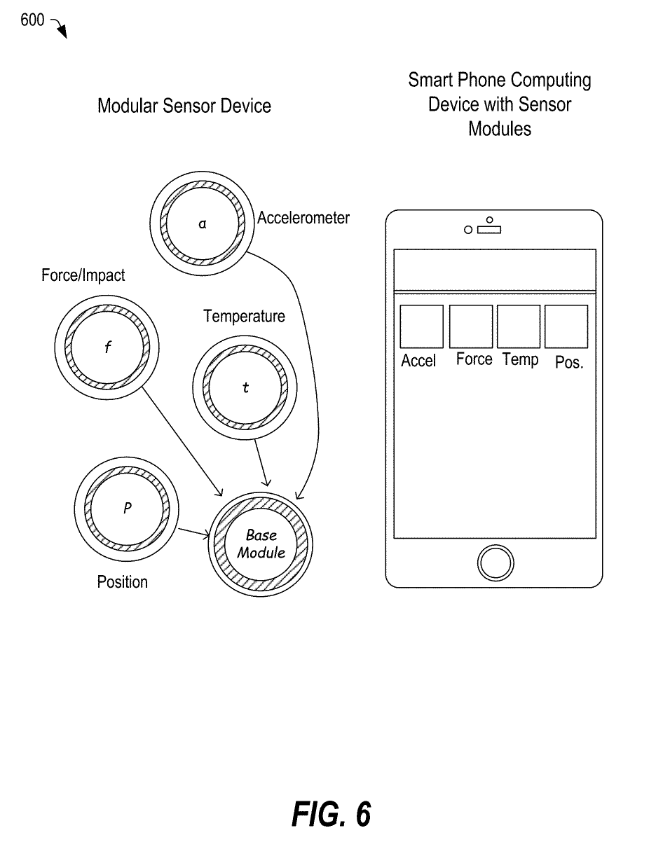

FIG. 6 depicts a system 600 including multiple sensor modules 104 and a base unit 102 defining a modular sensor device and a computing device 106 with sensor applications, in accordance with certain embodiments of the present disclosure. One or more of the sensor modules 104 (accelerometer, position, force/impact, temperature, and so on) may be stacked on the base module 102 to form a sensor device. The sensor device may then communicate data to one or more applications executed by a processor of the computing device 106, such as a smart phone.

In the illustrated example, the sensor modules 104 and the base module 102 have substantially cylindrical shapes. In other embodiments, the sensor modules 104 and the base module 102 may have rectangular prism shapes. Other embodiments are also possible.

Further, in the illustrated example, the instructions executable by the processor of the computing device 106 can be implemented in a single application. In other embodiments, the application on the computing device 106 may download the particular instructions set when the particular sensor module 104 is detected via communication with the base module 102.

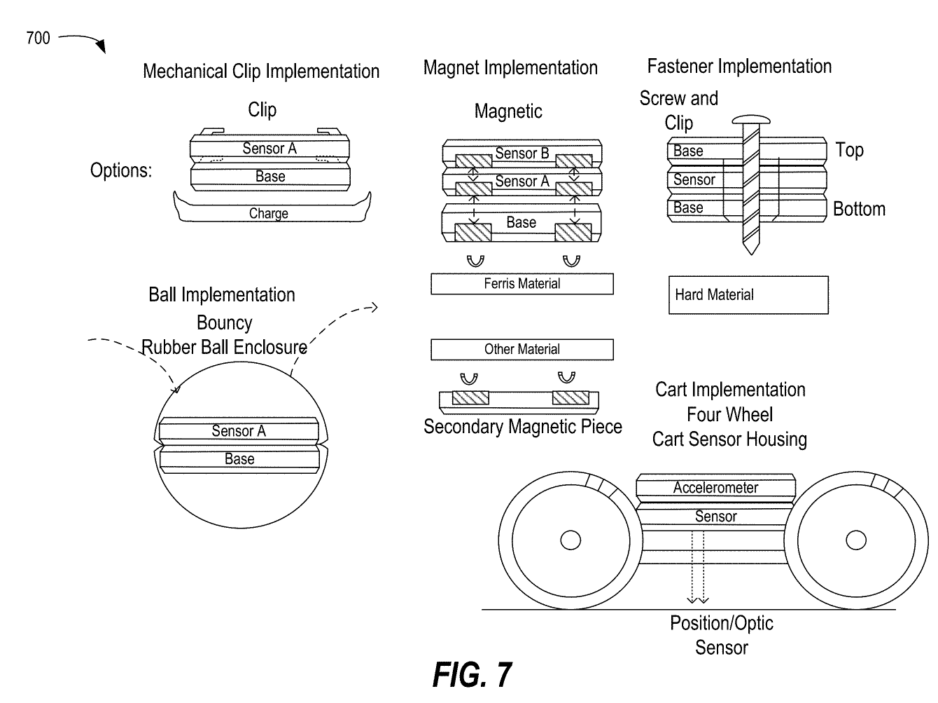

FIG. 7 depicts multiple implementations 700 of sensor devices including one or more sensor modules 104 and a base module 106, in accordance with certain embodiments of the present disclosure. In a mechanical clip implementation, the base module and the one or more sensor modules may be provided with clips, which may be manipulated by a user to engage and disengage a next module in a stack. The base module 102 may rest on the charger to inductively recharge a battery of the base module 102.

In the ball implementation, the base module 102 and sensor module(s) 104 may be secured within a rubber ball housing. The ball housing may be threaded or otherwise configured to open and close in order to selectively adjust the sensor device, as needed. The sensor module 104 may include accelerometers, impact sensors, and other types of sensors.

In the magnet implementation, each of the sensor modules 104 and the base module 102 may be provided with one or more magnets. In this implementation, magnetic attraction of adjacent magnets may secure the stack (e.g., the sensor modules 104 to one another and to the base module 102). Further, the magnets may be used to secure the sensor device to a structure, such as a substrate. As shown, a secondary magnetic plate (or complementary magnetic element) may be used to provide a magnetic attraction spanning a thickness of a substrate to secure the sensor device to the substrate.

In a fastener implementation, one or more of the base module 102 and the sensor modules 104 may include an opening sized to receive a fastener, such as a screw, which may be used to secure the base module 102 and the sensor module 104 to a substrate.

In a cart implementation, the cart may include a receiving area configured to receive and secure the sensor device stack to the cart substrate. In an example, the base module 102 may be secured to the cart substrate, and the sensor modules 104 may be secured to the base module 102 via the magnets. In some embodiments, at least the base module 102 may be coupled to the cart via one or more of the above-described attachment mechanisms.

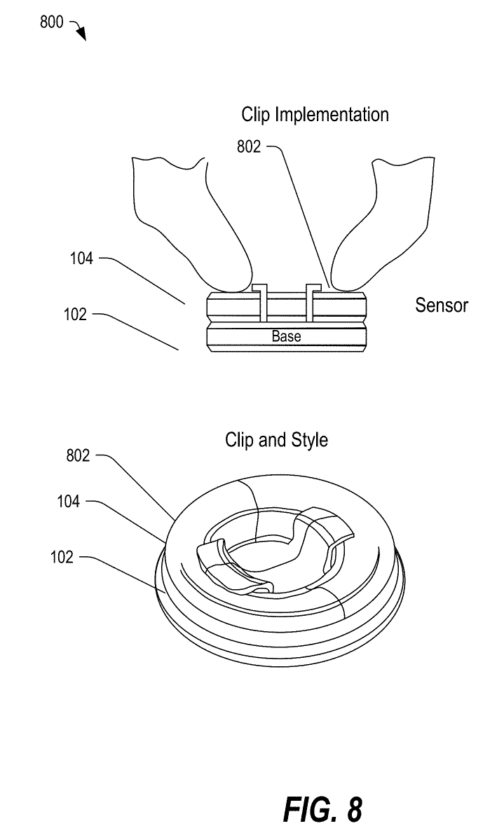

FIG. 8 depicts a clip attachment implementation 800 configured to releasably couple the sensor module 104 to the base module 102, in accordance with certain embodiments of the present disclosure. In some embodiments, the base module 102 may include or be coupled to a clip 802, which may extend through a center portion of the sensor module 104 to engage a surface of an underlying module (sensor or base) to secure the sensor module 104 to an underlying module. By squeezing the clip 802, the sensor module 104 may be disengaged from the stack. Other embodiments are also possible.

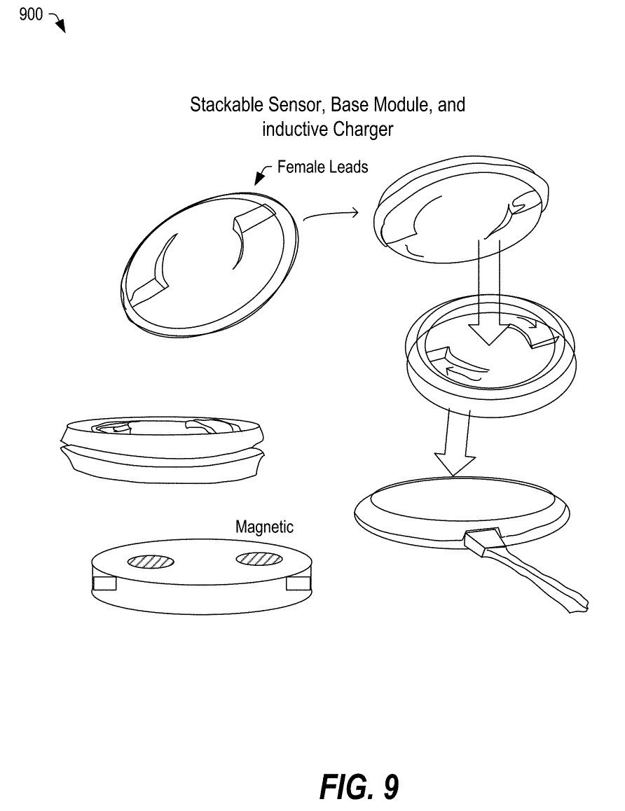

FIG. 9 depicts a sensor system 900 including a stackable sensor module 104, base module 102 and inductive charger, in accordance with certain embodiments of the present disclosure. In the sensor system, the base module 102 includes a female attachment mechanism configured to engage and secure a male attachment mechanism on a first side of a sensor module 104. In some examples, the sensor module 104 may be aligned to the base module 102 and may be secured to the base module 102 by a partial turn or twist. The second side of the sensor module 104 may include a female attachment mechanism configured to engage a first side of a next sensor module 104, and so on. The base module 102 may include a male or female attachment mechanism on a side opposite the sensor module 104 to engage a charging device, such as an inductive recharger. In some instances, the attachment mechanism may include electrical connections. Other embodiments are also possible.

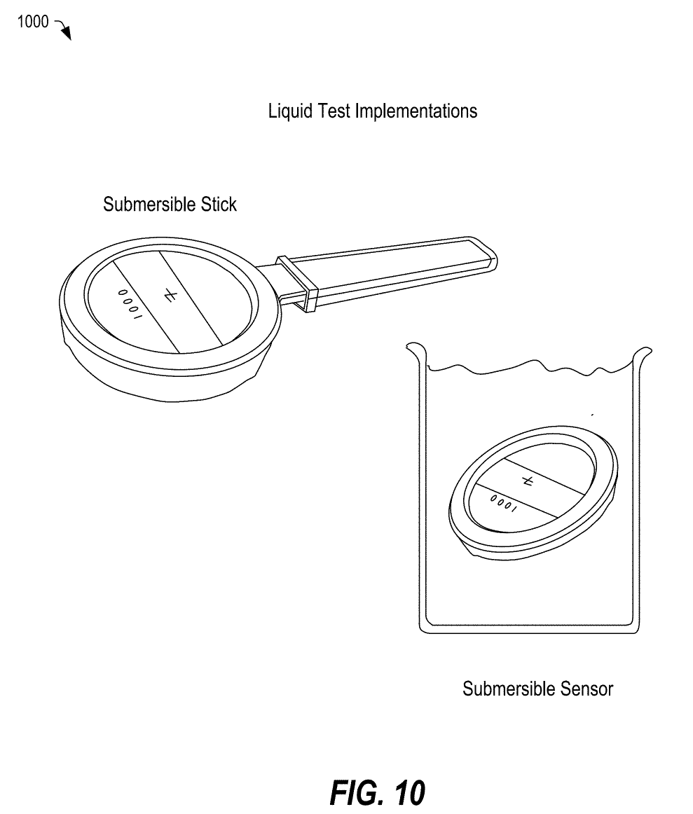

FIG. 10 depicts a liquid submersible sensor stack 1000, in accordance with certain embodiments of the present disclosure. The sensor stack 1000 may be coupled to a tube or sampling element to perform a fluid sampling operation. Alternatively, the sensor stack 1000 may be immersed in a fluid bath. In this example, the sensor device may be formed by a base module 102 and one or more sensor modules 104 coupled together. In a particular embodiment, a water-tight ring or seal may be positioned about the peripheral edges of the sensor device to produce a water-tight device, which can be exposed to fluid. Alternatively, the seal may be formed between a first sensor and the base module. Other embodiments are also possible.

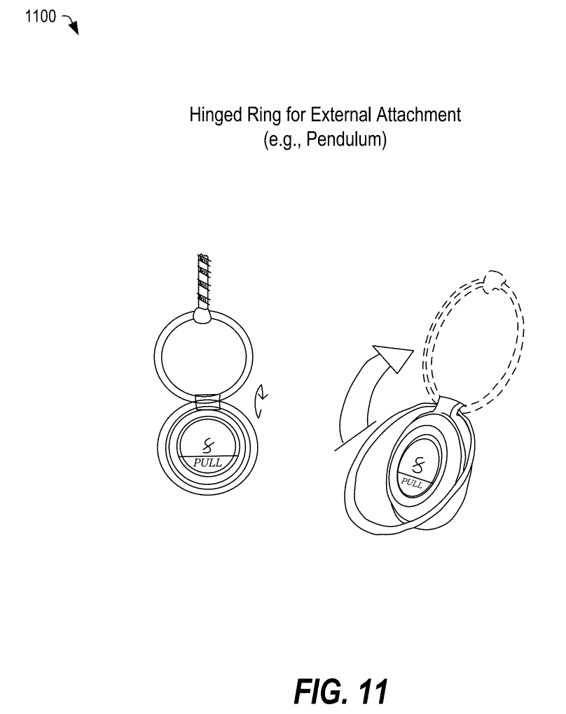

FIG. 11 depicts a sensor system 1100 including a hinged ring for external attachment, in accordance with certain embodiments of the present disclosure. In an example, the sensor device may be formed by a base module 102 and one or more sensor modules 104 coupled together. A mounting ring may be attached to at least one edge of the sensor device. The sensor module 102 may include motion sensors (e.g., gyroscopes, accelerometers, position sensors, and so on), which may produce measurement data corresponding to pendulum motion). In some instances, the mounting ring may be attached by a hinge, and the ring can be extended to facilitate attachment. Other embodiments are also possible.

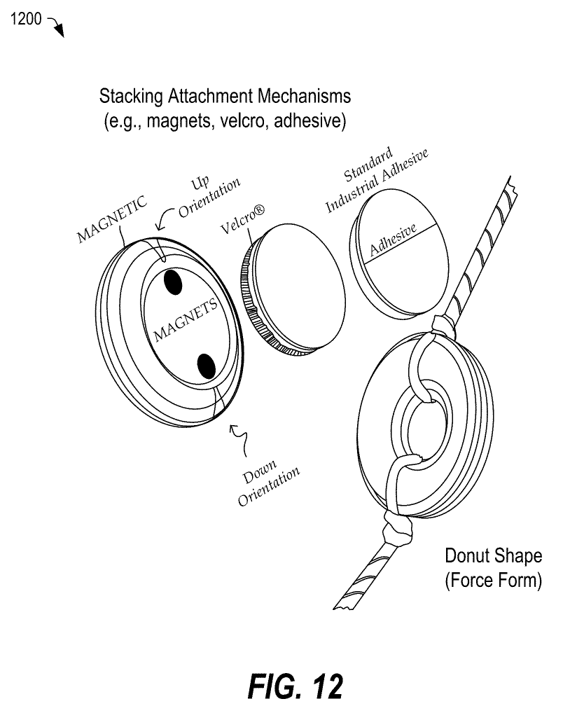

FIG. 12 depicts multiple attachment mechanisms 1200 for coupling the sensors to each other and to the base module 102 and for coupling the sensor stack (e.g., a plurality of interconnected sensor modules 104) to other devices, in accordance with certain embodiments of the present disclosure. In this example, the sensor device may be coupled by magnets, hook and eye material, adhesive, a fastener, and so on. Further, the base module 102 and the sensor modules 104 may be formed as stacked rings having a central opening to allow a string, for example, to be tied about opposing sides to measure force applied to the strings. Other embodiments are also possible.

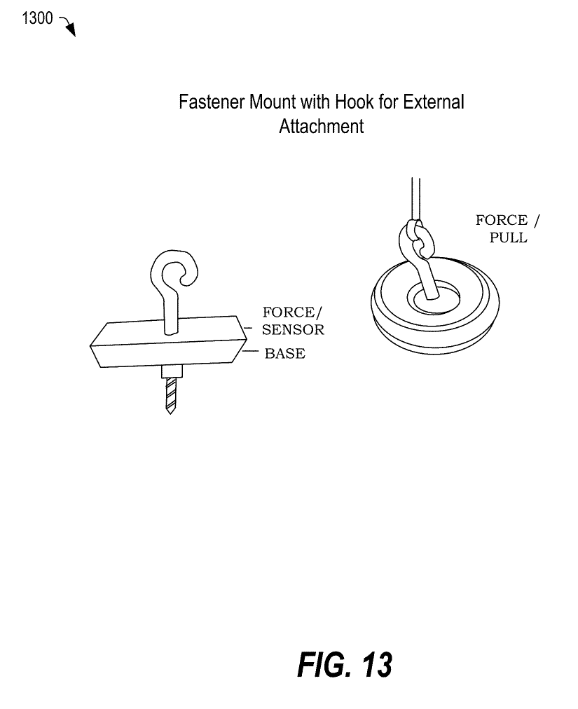

FIG. 13 depicts a sensor device 1300 including a fastener mount with a hook configured to engage the sensor device (base module 102 and one or more sensor modules 104), in accordance with certain embodiments of the present disclosure. A string may be tied to the hook for a force measurement or other measurements.

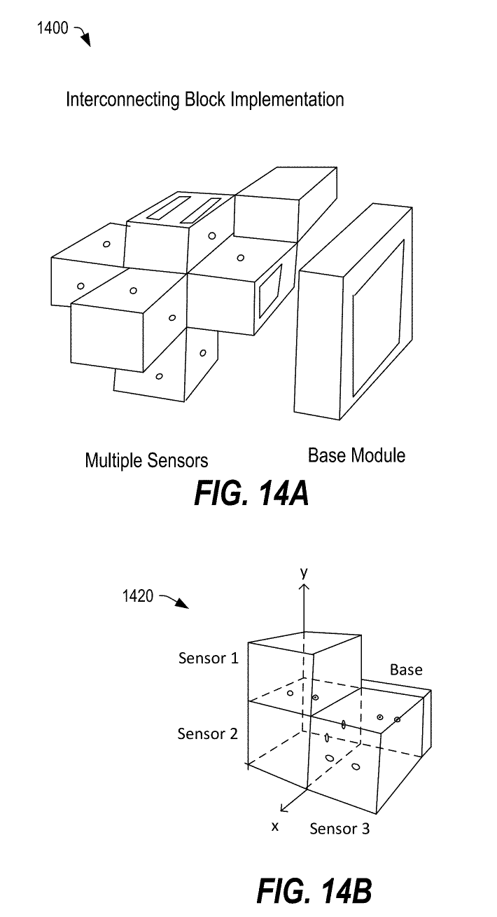

FIGS. 14A and 14B depict an interconnecting block implementation of the sensor modules 104 and the base module 102, in accordance with certain embodiments of the present disclosure. In the illustrated example of FIG. 14A, the interconnecting block implementation 1400 can include multiple sensor modules 104 and a base module 102 (or multiple base modules). The block-shaped modules may be stacked in a variety of configurations.

In FIG. 14B, the interconnecting block implementation 1420 can include a base module 102 and a plurality of sensor modules 104. Other configurations are also possible.

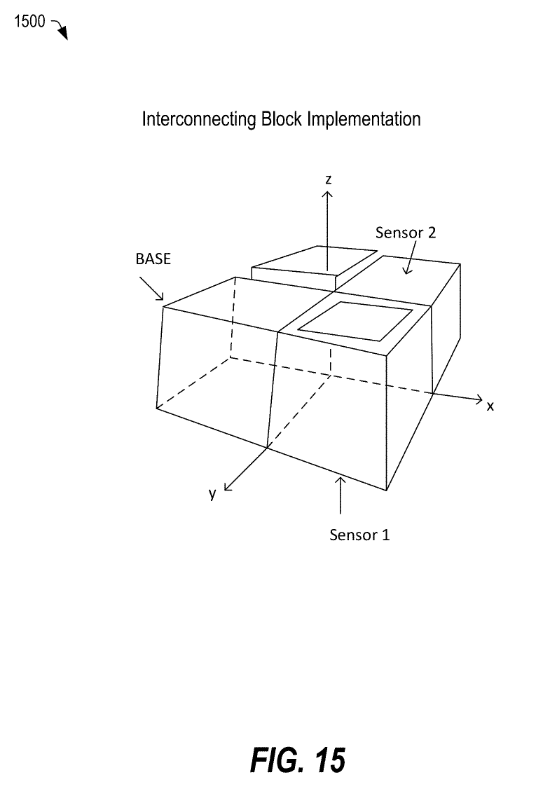

FIG. 15 depicts an interconnecting block implementation 1500 of the sensor modules 104 and the base module 102, in accordance with certain embodiments of the present disclosure. The interconnecting block configuration shows multiple sensor modules 104 and a base module 102.

In an example, the embodiments of FIGS. 14A-15 are intended to show that the blocks or modules may be interconnected in a variety of ways. Conductive elements may be provided on multiple sides of each module, enabling interconnectivity from any side. Other embodiments are also possible.

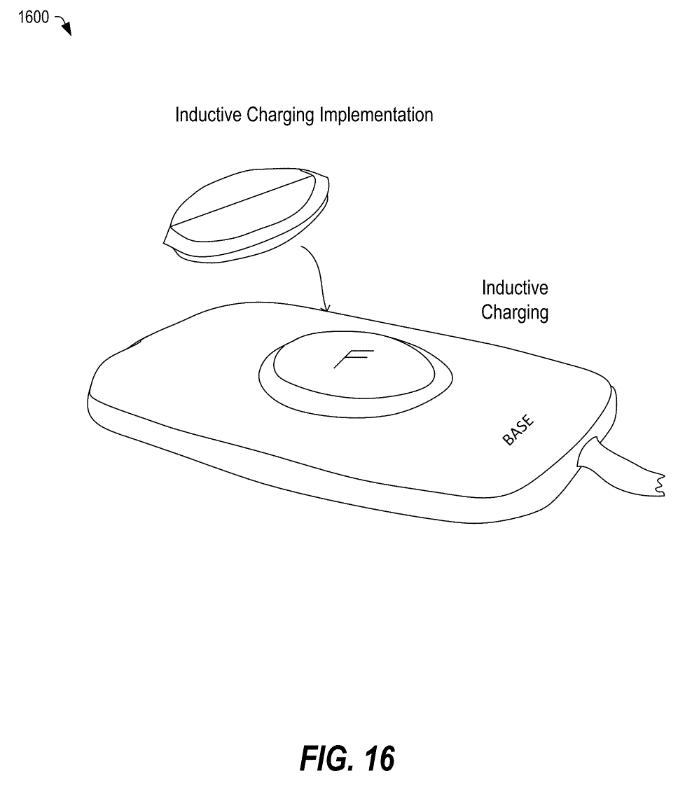

FIG. 16 depicts a system 1600 including a module and an inductive charging base, in accordance with certain embodiments of the present disclosure. The inductive charging base may be coupled to a computing device or to another power source to receive power for the inductive charging operation.

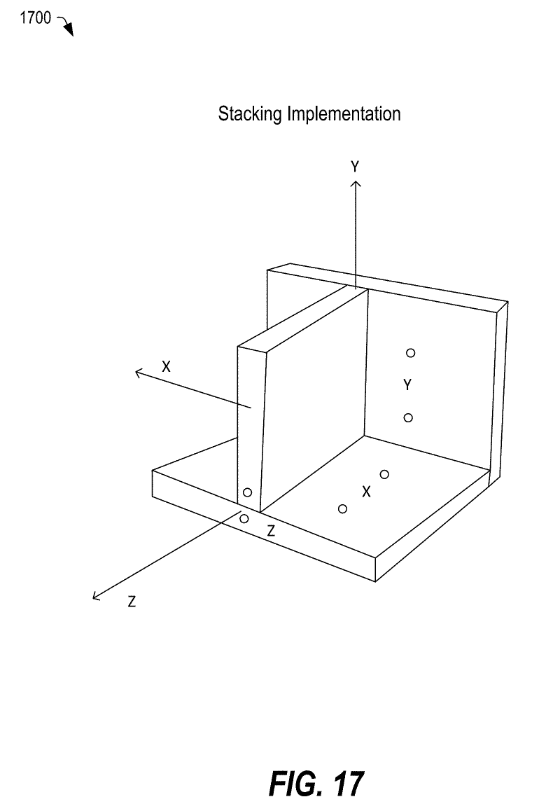

FIG. 17 depicts a three-dimensional representation 1700 of the interconnected block configurations of FIGS. 14A-15, in accordance with certain embodiments of the present disclosure. In the illustrated example, conductors may be provided in two or more sides or edges to enable connectivity in a variety of configurations. In some embodiments, the modules may be interconnected edge-to-edge or edge-to-side to provide further connection versatility.

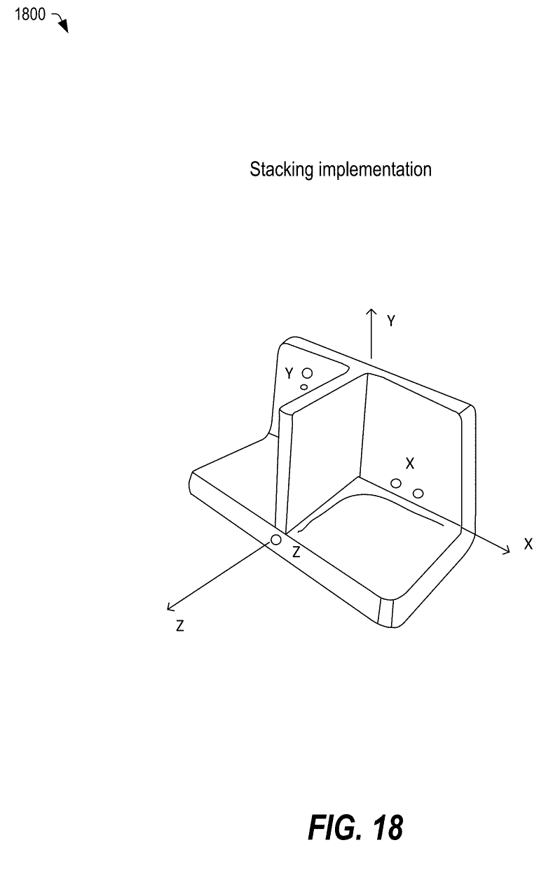

FIG. 18 depicts a three-dimensional representation 1800 of the interconnected block configurations of FIGS. 14A-15, in accordance with certain embodiments of the present disclosure. The interconnected blocks are shown in an orientation that differs from that of FIG. 17.

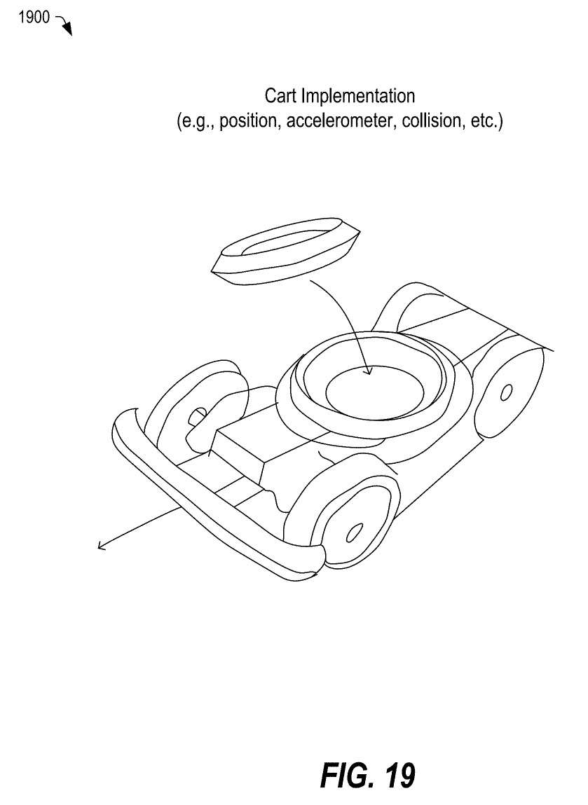

FIG. 19 depicts a sensor system 1900 including a stacked sensor device coupled to a cart, in accordance with certain embodiments of the present disclosure. The stacked sensor device can be coupled to a four-wheel cart or car to enable various experiments. In this example, the cart may be provided with a receiving feature. In other embodiments, magnets or other attachment mechanisms may be used.

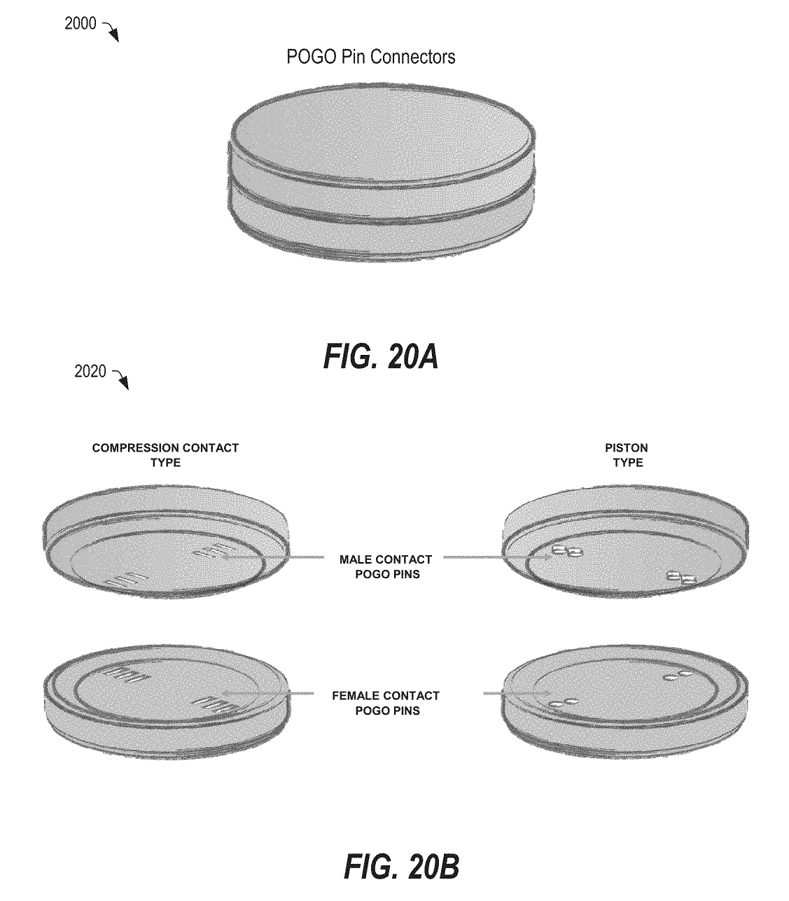

FIGS. 20A and 20B depict a stacked sensor device and different types of electrical connections, in accordance with certain embodiments of the present disclosure. In FIG. 20A, the base module is coupled to one or more sensor modules to form a sensor device 2000. It should be appreciated that the base module may be coupled to any number of transducers, including sensors, actuators, and other devices.

In FIG. 20B, different connector configurations 2020 are shown. In an example, the sensor module may include male contacts. The male contacts may be implemented as pogo pin type connectors. As used herein, the pogo pin is a device used in electronics to establish a (usually temporary) connection between two circuits. The pogo pins may include a slender cylinder containing two sharp, spring-loaded pins which can be pressed to make secure contacts with the two circuits and thereby connect them together. Some examples include springs and a locking mechanism to facilitate engagement and disengagement. The base module may include corresponding female contact pins. The contact pins may both electrically and physically couple the sensor module to the base module, or one sensor module to another sensor module.

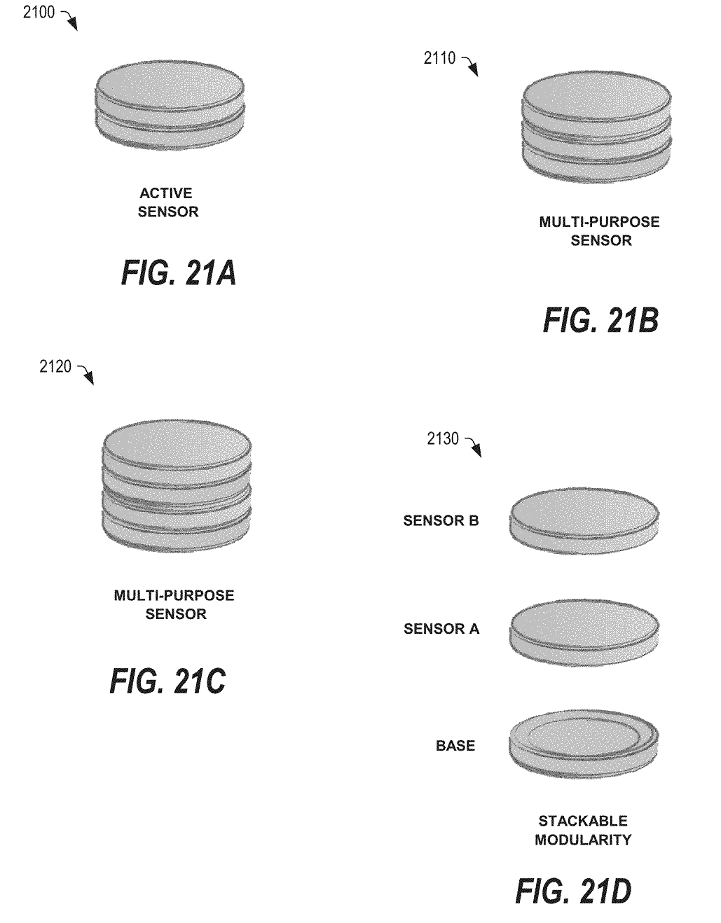

FIGS. 21A-21D depict different configurations of sensor modules and one or more base modules, in accordance with certain embodiments of the present disclosure. In FIG. 21A, an active sensor 2100 is shown. In FIG. 21B, a multi-purpose sensor is shown that includes multiple sensor modules coupled to the base module.

In FIG. 21C, a multi-purpose sensor device 2120 is shown that includes multiple sensor modules and multiple base modules. FIG. 21D depicts an exploded view of a sensor device including a base module and two sensor modules. Other embodiments are also possible.

It should be appreciated that, while the sensor modules and the base modules depicted in the figures are shown as being cylindrical prism components, other shapes are also possible. For example, the sensor modules can be implemented as rectangular prism or another shape.

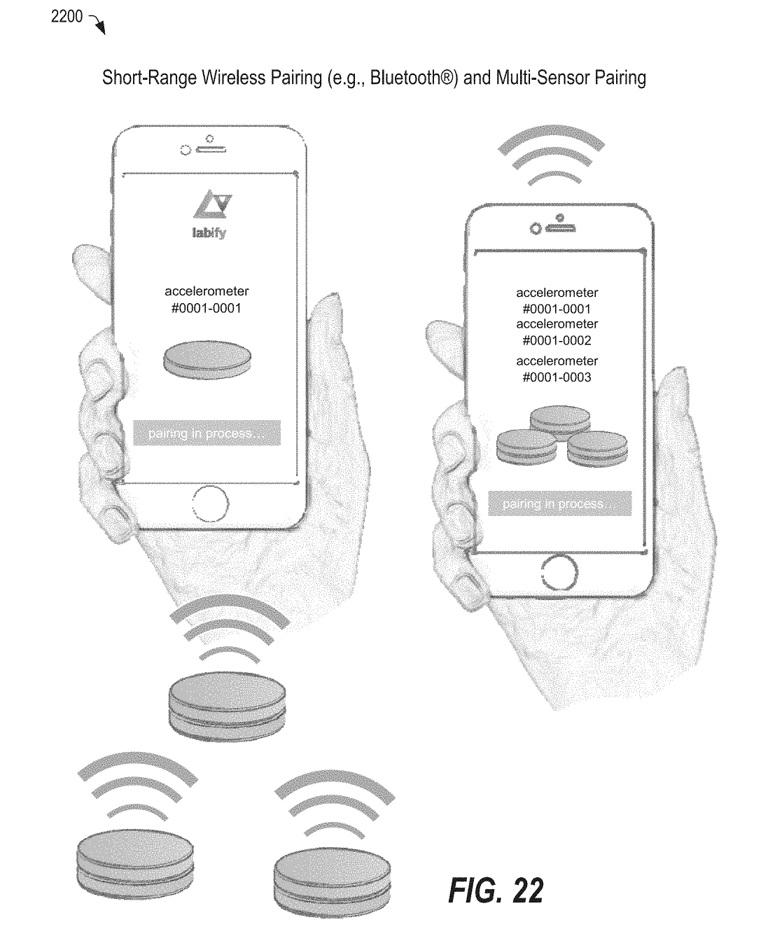

FIG. 22 depicts a short-range wireless pairing and multi-sensor pairing of a smart phone to a plurality of sensor devices, in accordance with certain embodiments of the present disclosure. The system 2200 includes a first smart phone that is communicatively coupled to one sensor and second smart phone that is coupled to multiple sensor devices via a short-range wireless connection.

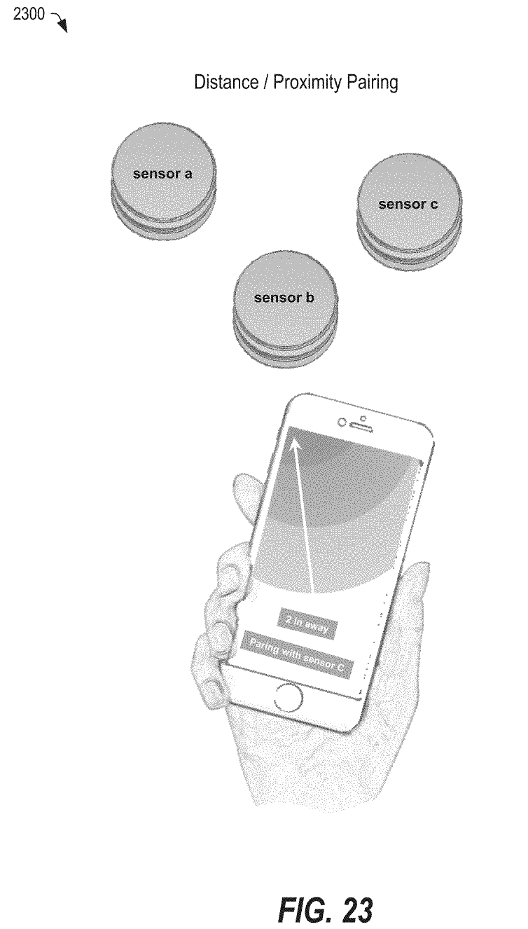

FIG. 23 depicts distance/proximity pairing of a smart phone to one or more sensor devices, in accordance with certain embodiments of the present disclosure. The system 2300 includes a smart phone configured to determine proximity to one or more sensors.

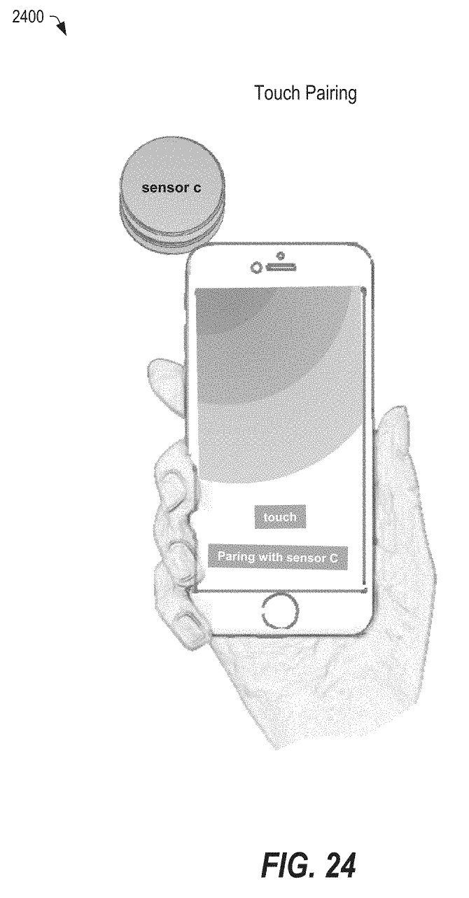

FIG. 24 depicts touch pairing 2400 of a smart phone to a sensor device, in accordance with certain embodiments of the present disclosure. In this example, the smart phone may pair with a sensor device by touching a portion of the smart phone to a selected sensor device.

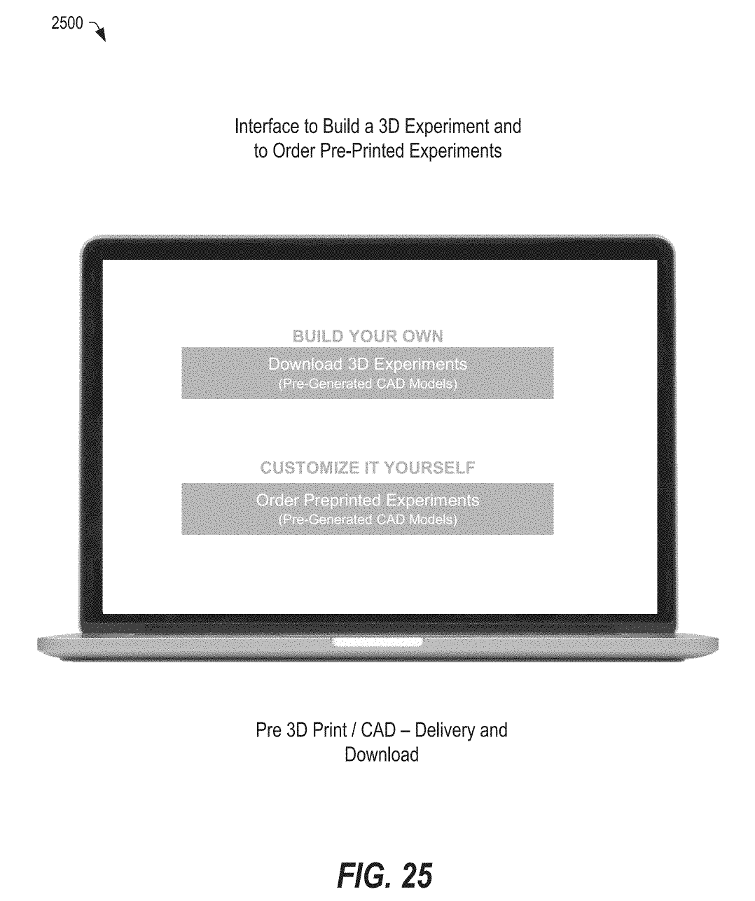

FIG. 25 depicts a laptop computer 2500 including a display showing an interface to build a 3D experiment and to order pre-printed (already prepared) experiments, in accordance with certain embodiments of the present disclosure.

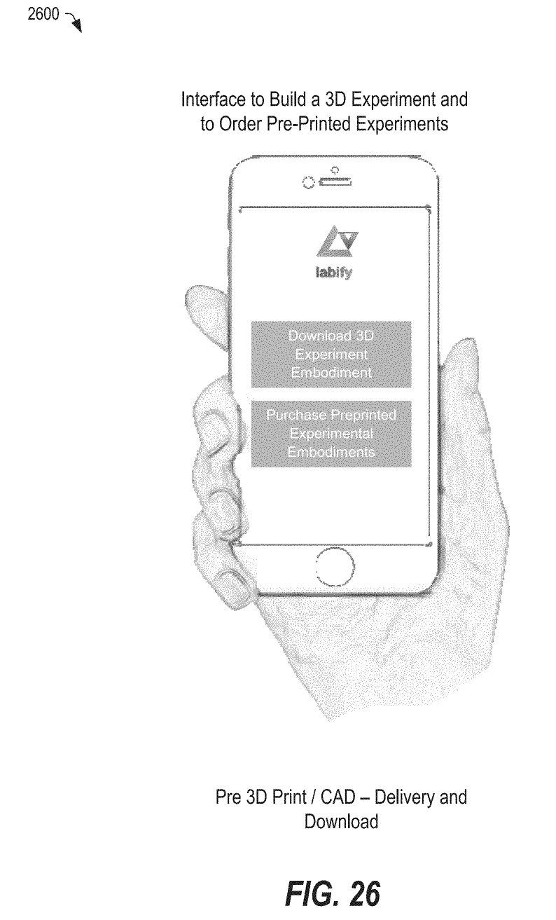

FIG. 26 depicts a smart phone 2600 including a display showing an interface to build a 3D experiment and to order pre-printed (already prepared) experiments, in accordance with certain embodiments of the present disclosure.

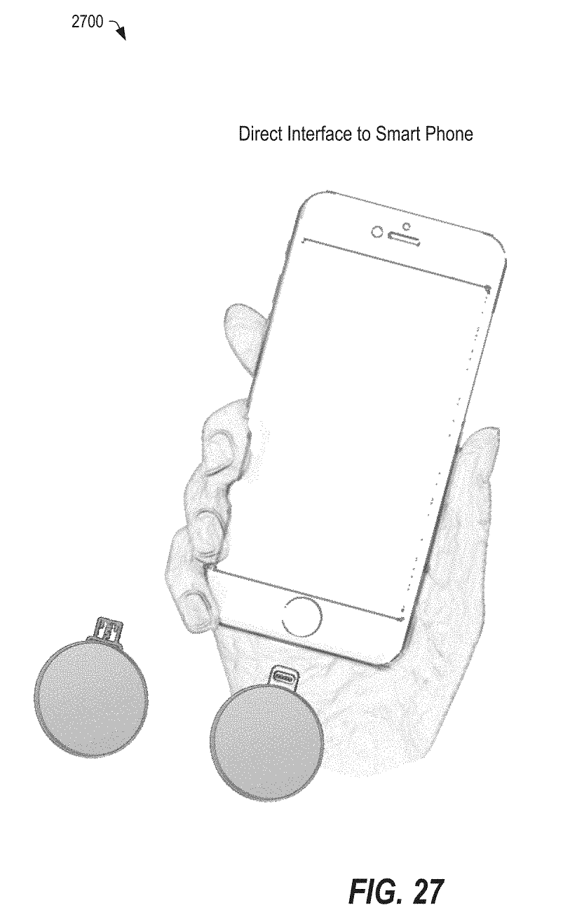

FIG. 27 depicts a system 2700 including a smart phone and sensor devices configured to interface directly to the smart phone, in accordance with certain embodiments of the present disclosure. In this instance, the base module or one of the sensor modules may include a male connection interface configured to engage a port or female interface of the smart phone. The connection may be used to perform an experiment. Alternatively, the connection may be used to communicate data from the sensor to the smart phone. Other embodiments are also possible.

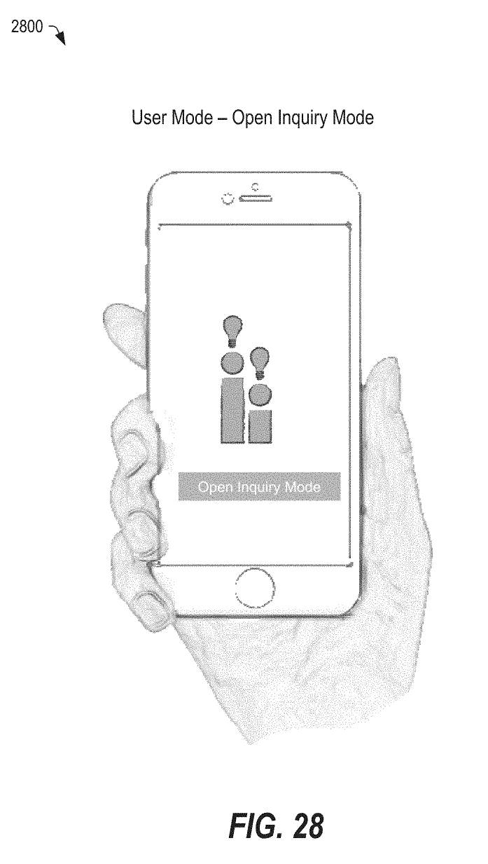

FIG. 28 depicts a smart phone 2800 including an interface depicting an open inquiry mode, in accordance with certain embodiments of the present disclosure. The open inquiry mode may allow the user to view available devices to which the smart phone 2800 may be paired.

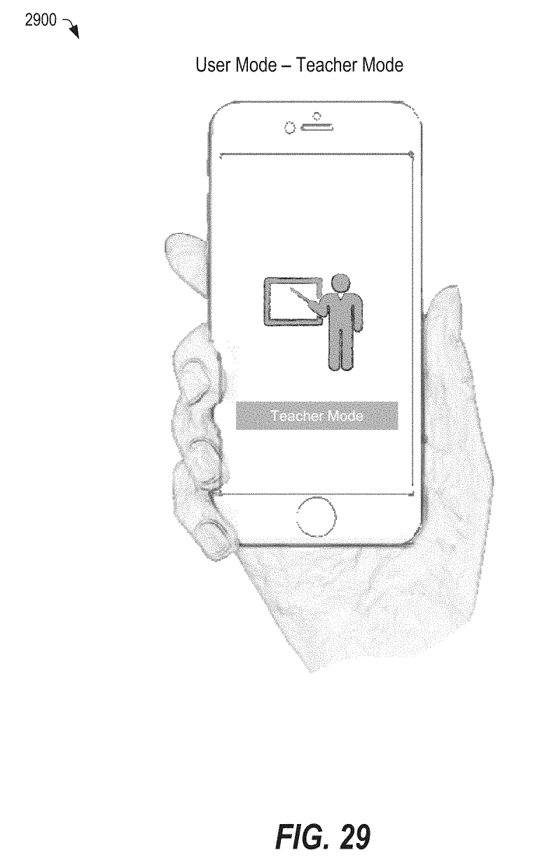

FIG. 29 depicts a smart phone 2900 including an interface depicting a teacher mode, in accordance with certain embodiments of the present disclosure. An instructor may access this mode via the interface to configure an experiment.

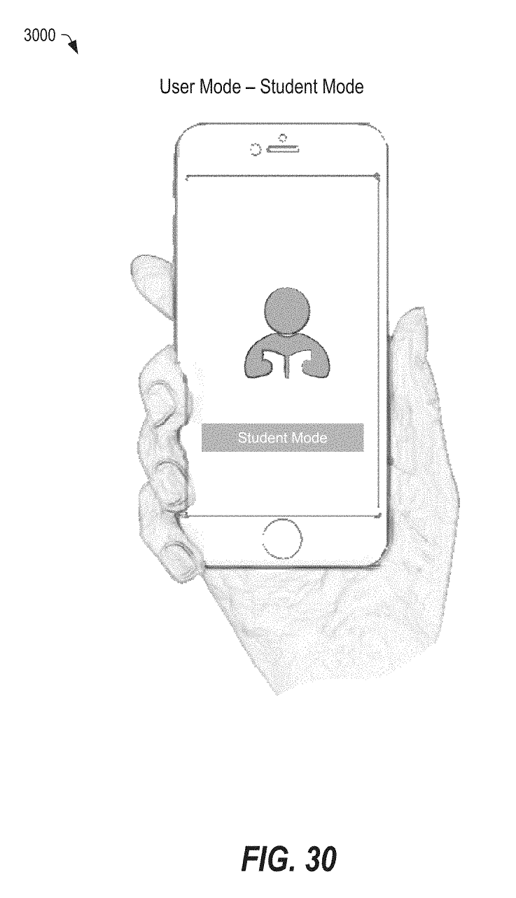

FIG. 30 depicts a smart phone 3000 including an interface depicting a student mode, in accordance with certain embodiments of the present disclosure. The student may access this interface to perform the experiment, to configure the sensor system, and so on.

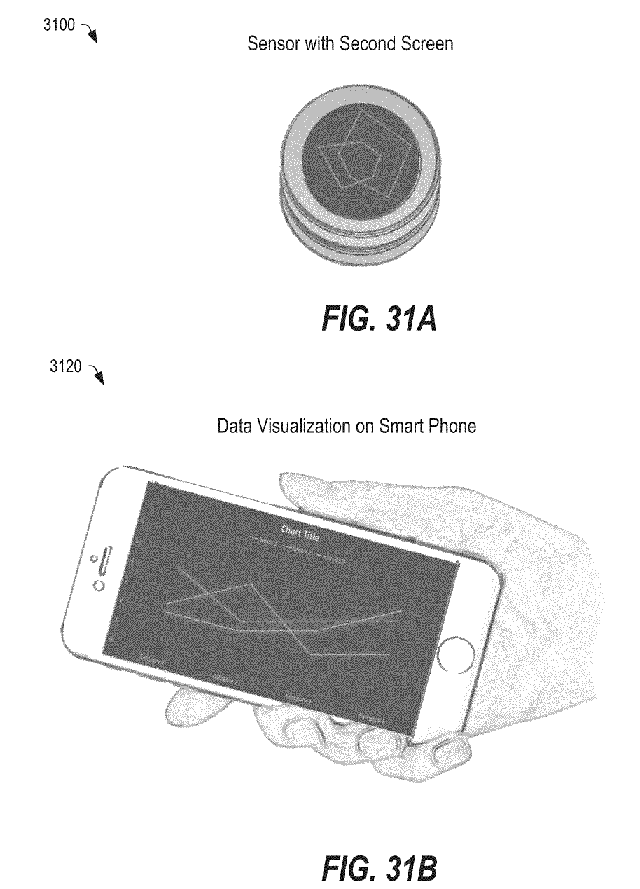

FIGS. 31A and 31B depict a sensor device 3100 with a display and a smart phone 3120 displaying a data visualization, in accordance with certain embodiments of the present disclosure. In FIG. 31A, at least one of the sensor modules 104 is provided with a display.

In FIG. 31B, a computing device (smartphone) is shown and generally indicated at 3120. The touchscreen interface of the smartphone may depict a visualization of data collected by the sensor.

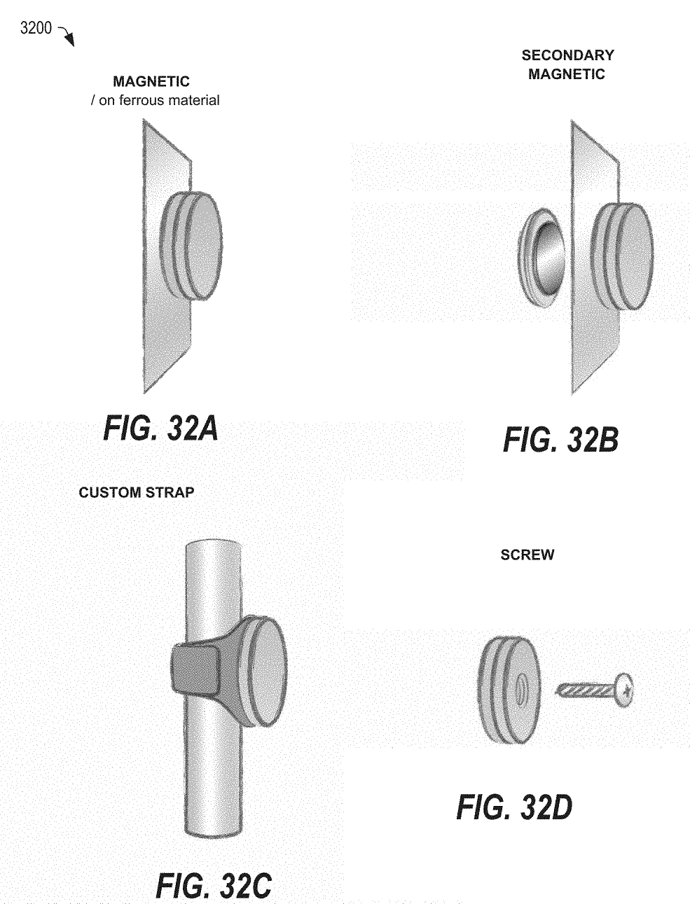

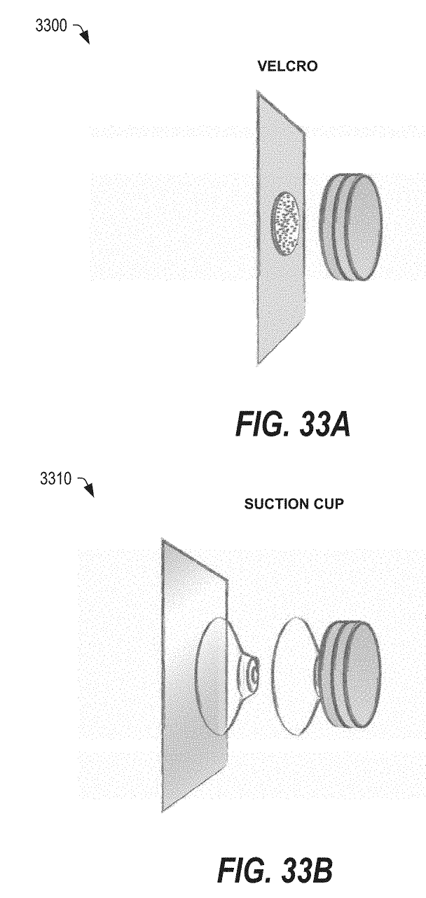

FIGS. 32A-32D depicts multiple possible attachment implementations, generally indicated at 3200, for coupling a sensor device to a member, in accordance with certain embodiments of the present disclosure. In FIG. 33A, the sensor device is magnetically coupled to a ferrous material. In FIG. 33B, a secondary magnet is provided on a second side of a substrate to establish a magnetic connection through a substrate.

In FIG. 32C, a strap may be configured to secure the sensor device to a pole. In an alternative embodiment, the strap may secure the sensor device to a user's arm or to a different structure. In the illustrated example, the strap secures the sensor device to a pole.

In FIG. 32D, a fastener may be used to secure the sensor device to a substrate. In this example, the sensor modules and the base module may include an opening sized to receive the fastener.

FIGS. 33A and 33B depict attachment implementations for coupling a sensor device to a substrate, in accordance with certain embodiments of the present disclosure. In FIG. 33A, a system 3300 includes a hook and eye structure (such as Velcro®) to secure the sensor device to a substrate. In some examples, a portion of the hook or eye structure may be fastened to the substrate by an adhesive, a fastener, or some other device.

In FIG. 33B, a system 3310 includes a suction cup coupled to the base module and configured to secure the sensor device to a substrate. In some embodiments, the suction cup may be clipped, threadably attached, or otherwise coupled to a receiving portion of the base module. Other embodiments are also possible.

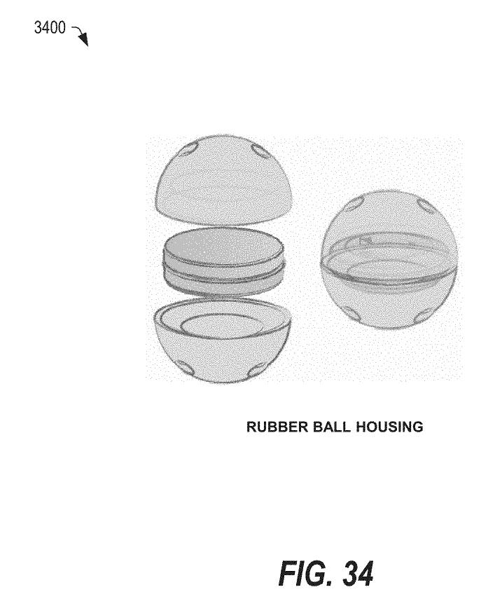

FIG. 34 depicts a rubber ball implementation 3400 including a rubber ball housing configured to secure a sensor device, in accordance with certain embodiments of the present disclosure. In this example, the sensor module 104 and the base module 102 may be coupled to one another and secured within the rubber ball housing. The sensor module 104 and the base module 102 may be configured to measure impacts, movement, and so on.

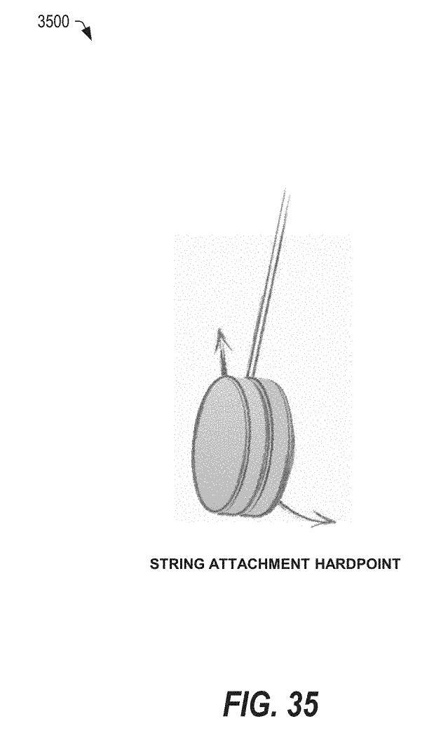

FIG. 35 depicts a sensor device 3500 configured to swing like a pendulum, in accordance with certain embodiments of the present disclosure. In this example, the string may be coupled to a hook, loop, or other feature of the sensor device.

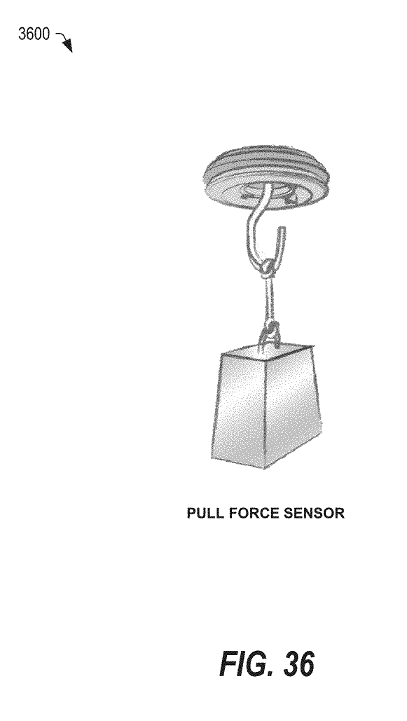

FIG. 36 depicts a sensor device 3600 configured to secure a weight on a hook and to determine a pull force, in accordance with certain embodiments of the present disclosure. The sensor device 3600 may include a feature configured to engage the hook. In some embodiments, the hook may be integrally formed as part of one of the sensor modules. In other embodiments, the hook may be threadably attached to the sensor device.

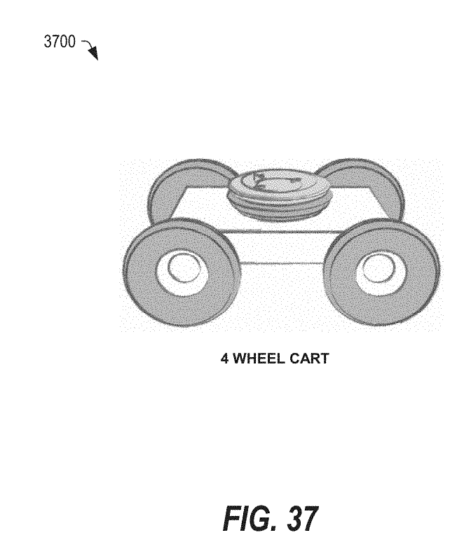

FIG. 37 depicts a system 3700 including a four-wheel cart having a sensor device mounted thereon, in accordance with certain embodiments of the present disclosure. The sensor device may be coupled to the cart by any of the above-described attachment mechanisms.

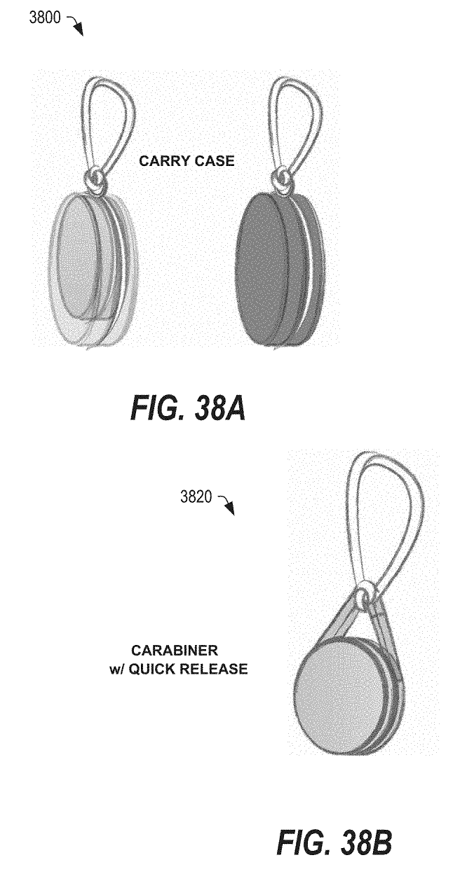

FIGS. 38A and 38B depict carrying mechanisms configured to carry the sensor device, in accordance with certain embodiments of the present disclosure. In FIG. 38A, the sensor device 3800, including the base module 102 and one or more sensor modules 104, may be encapsulated within a carrying case, which may include a loop that can be used to attach the carrying case to another device.

In FIG. 38B, the sensor device 3820 is secured by a carbiner with a quick release. The sensor device 3820 may include a base module 102 and one or more sensor modules 104.

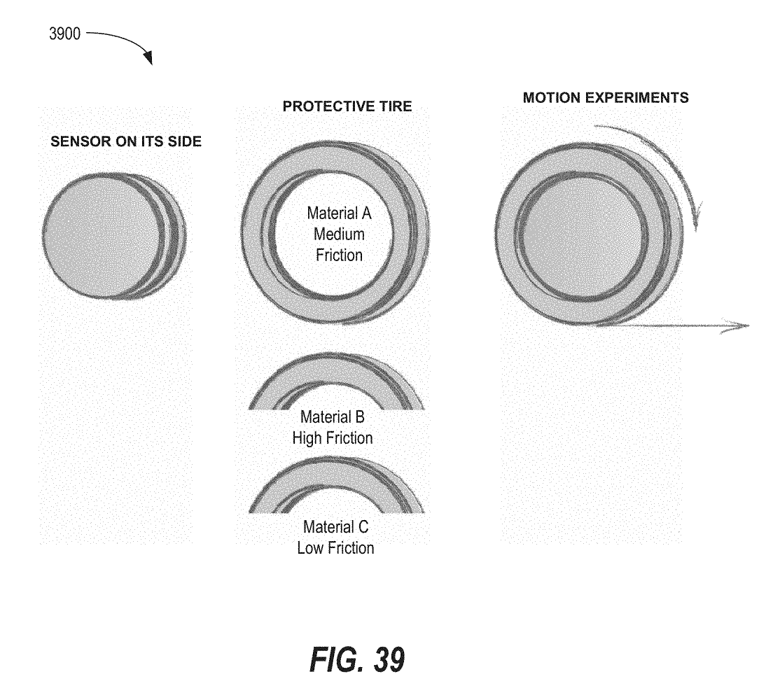

FIG. 39 depicts a system 3900 including a sensor device including a protective ring or tire of various materials, in accordance with certain embodiments of the present disclosure. The protective ring may be used to encircle the sensor device and to provide a desired level of friction (for example). In the illustrated example, the protective ring may be formed from different materials having a high, medium or low friction.

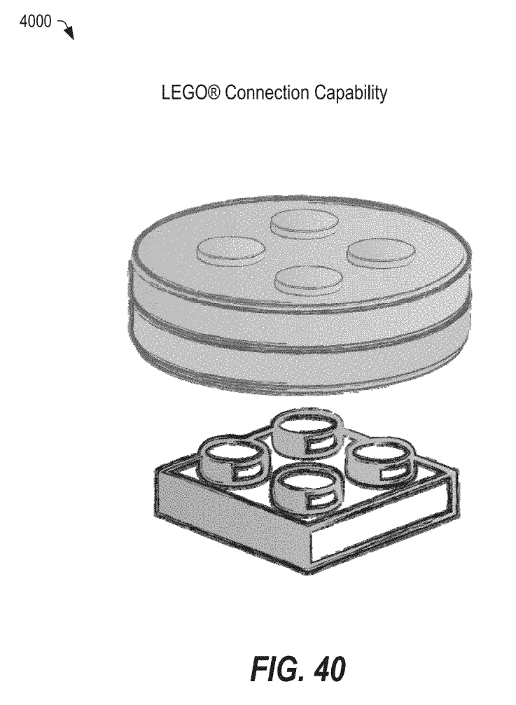

FIG. 40 depicts a sensor device 4000 configured to couple to an interlocking plastic building block (such as a LEGO® building block), in accordance with certain embodiments of the present disclosure. In this example, at least one of the modules may include a portion configured to couple to the interlocking plastic block.

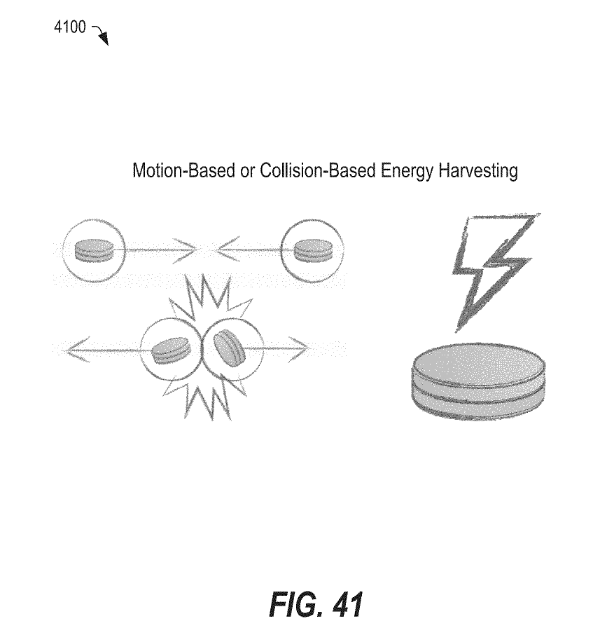

FIG. 41 depicts a motion-based or collision-based energy harvesting sensor device 4100, in accordance with certain embodiments of the present disclosure. In this example, energy from the collision or motion may be harvested to supplement the battery charge. Further, the energy from the collision may be registered as part of an experiment.

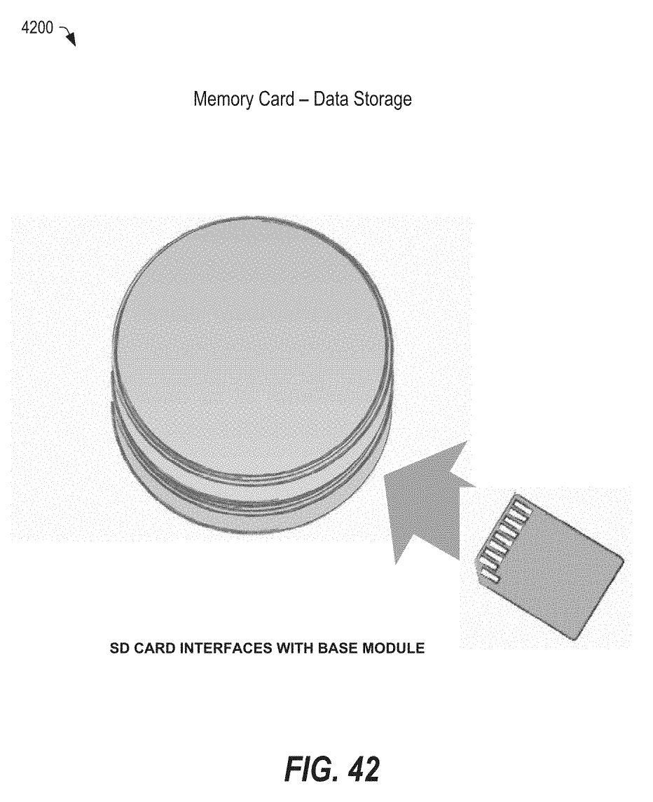

FIG. 42 depicts a sensor device 4200 including a memory card for data storage, in accordance with certain embodiments of the present disclosure. In some embodiments, the memory card may be removable. In some embodiments, the memory card may be added to supplement available memory. Other embodiments are also possible.

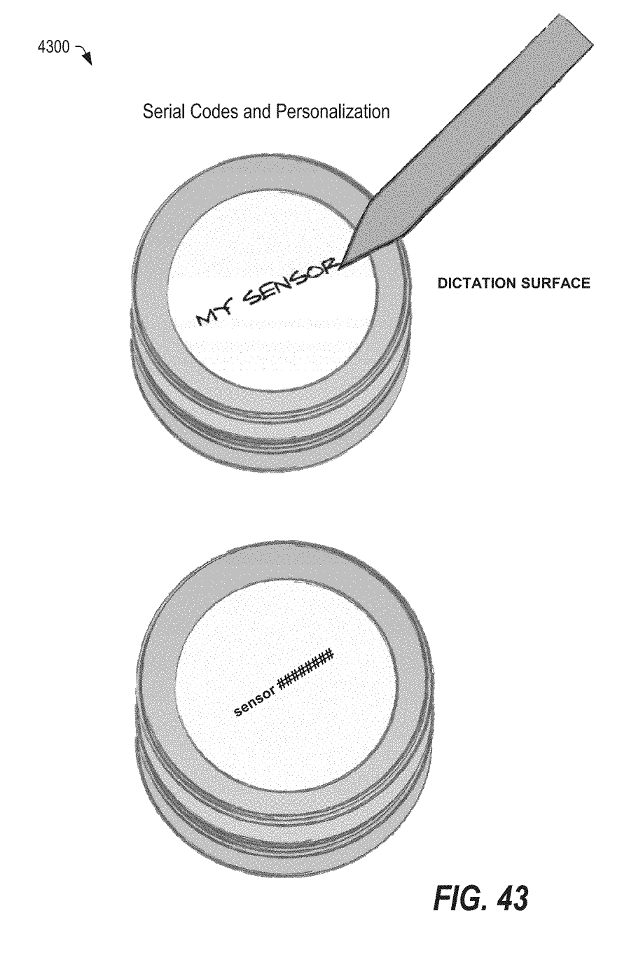

FIG. 43 depicts a sensor device 4300 including a surface configured to allow for personalization, to display an identifier, or both, in accordance with certain embodiments of the present disclosure. In some embodiments, the user may label the sensor using the touch-surface. Further, the device may maintain and optionally display the user label and/or the serial number.

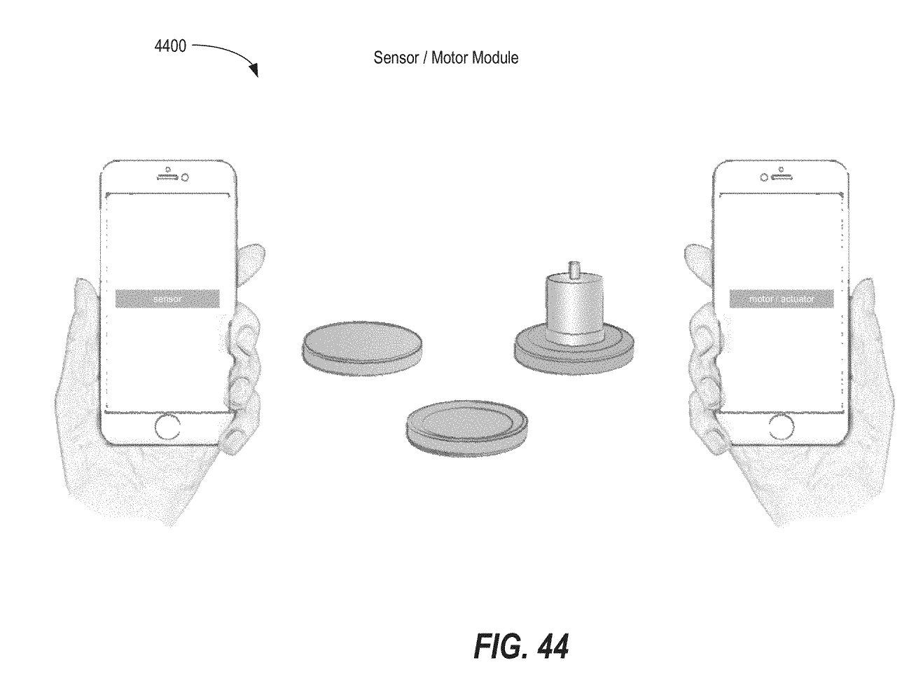

FIG. 44 depicts a smart phone 4400 configured to communicate with a sensor, a motor, or both, in accordance with certain embodiments of the present disclosure. While two different smart phones are shown, in some embodiments the same smart phone may be used to interact with the sensors and the motor. In some embodiments, the smart phone may be configured to interact with multiple transducers (sensors, actuators, motors, etc.) substantially simultaneously. Other embodiments are also possible.

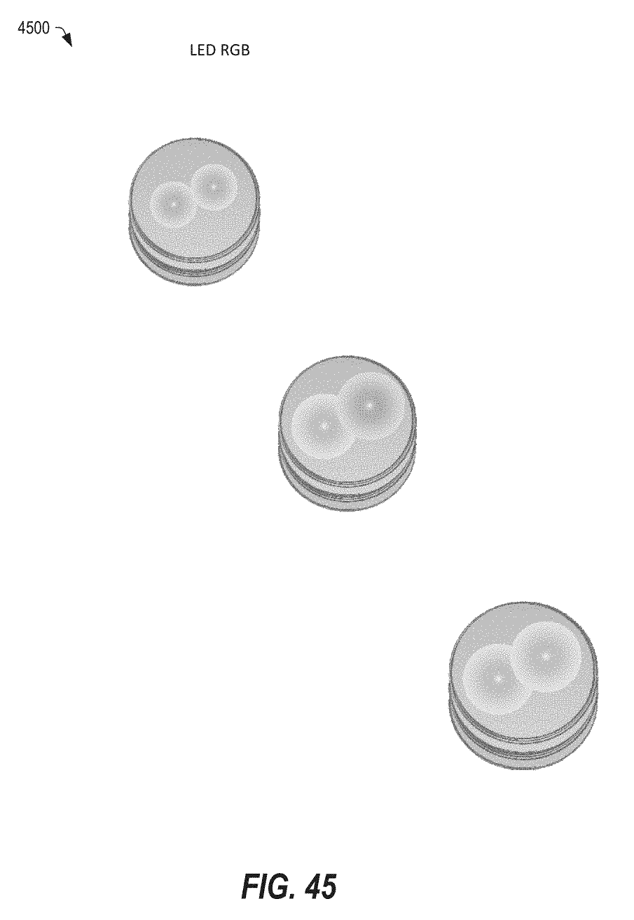

FIG. 45 depicts sensor devices 4500 including light-emitting diodes (LEDs), in accordance with certain embodiments of the present disclosure. The sensor devices 4500 may include the LEDs in the sensor modules 104, in the base module 102, or both. The housings of the sensor modules 104 and the base modules 102 may be sufficiently thin to allow light from the LED to be visible through the housing.

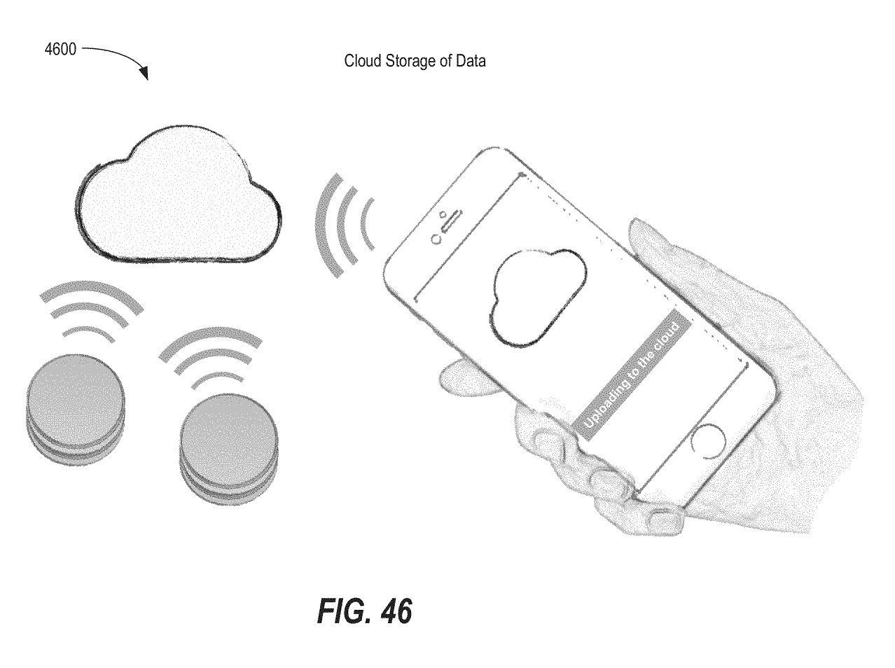

FIG. 46 depicts a system 4600 including a smart phone and sensor devices configured to upload and store data to a cloud-based server device, in accordance with certain embodiments of the present disclosure. The cloud may represent a network, such as the Internet, a WiFi network, a local area wireless network, another type of wireless network, or any combination thereof.

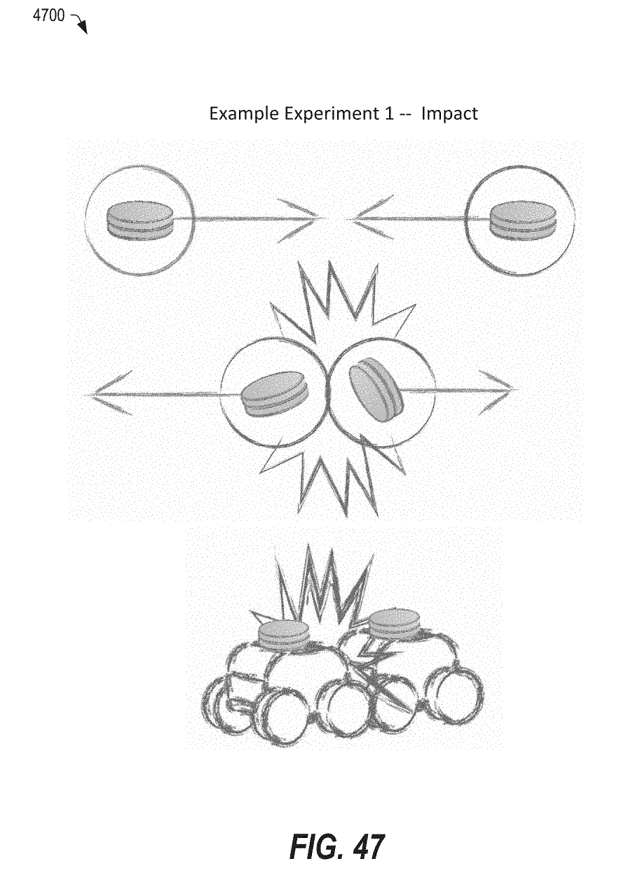

FIG. 47 depicts a portion 4700 of an example collision experiment using a sensor device, in accordance with certain embodiments of the present disclosure. The portion 4700 depicts two sensor devices on separate carriers that are configured to collide and measure various parameters associated with the collision.

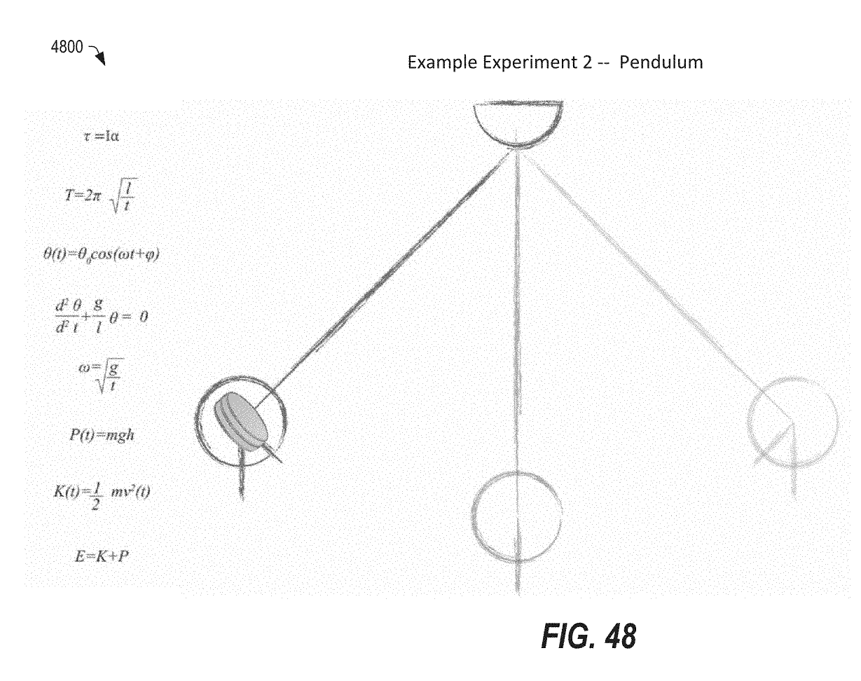

FIG. 48 depicts a portion of an example pendulum experiment 4800 using a sensor device, in accordance with certain embodiments of the present disclosure. The sensor device may include a base module 102 and one or more sensor modules 104 can include motion sensors, position sensors, orientation sensors, and so on, which can be used to measure and monitor pendulum motion.

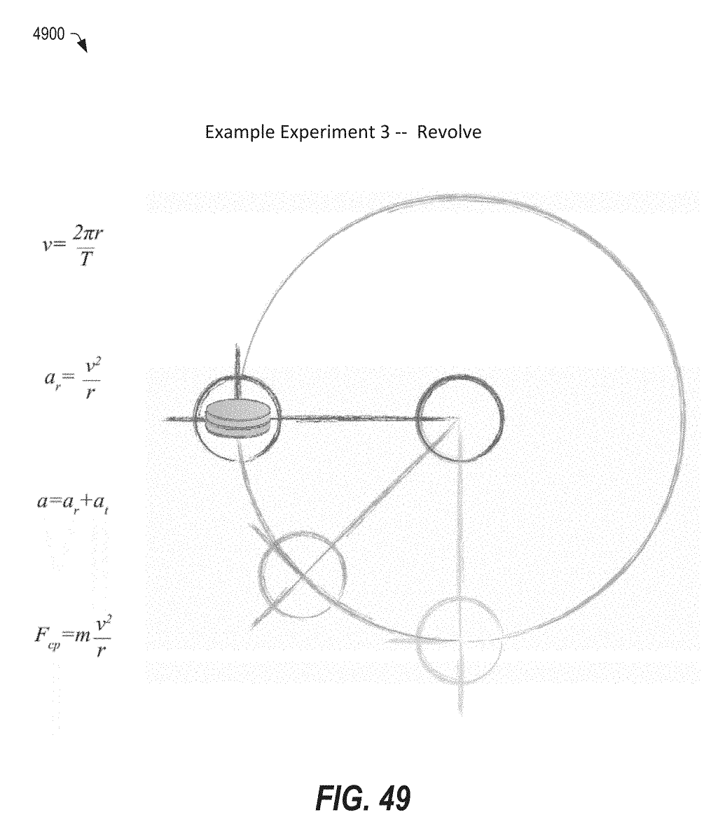

FIG. 49 depicts a portion of an example revolution experiment 4900 using a sensor device, in accordance with certain embodiments of the present disclosure. The sensor device includes a base module and one or more sensor modules configured to monitor motion and orientation as well as position. Other embodiments are also possible.

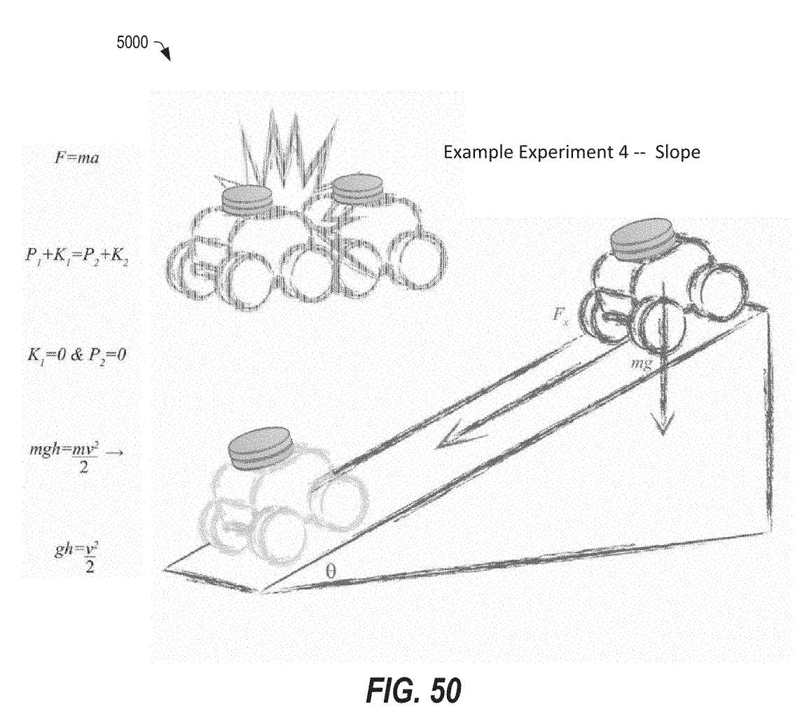

FIG. 50 depicts a portion of an example slope experiment 5000 using a sensor device, in accordance with certain embodiments of the present disclosure. As shown, the same sensor device may be used to monitor collisions between two cart devices. Other embodiments are also possible.

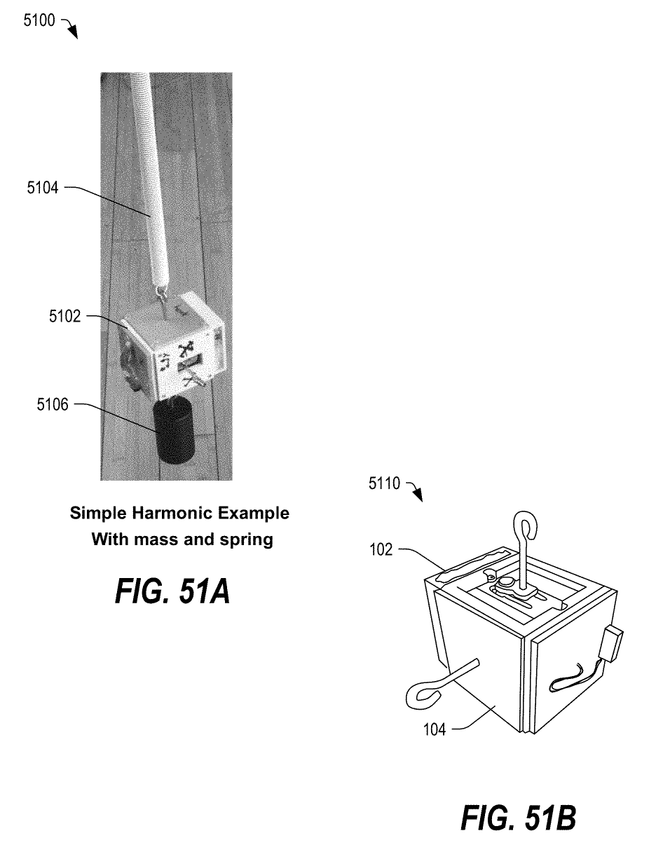

FIGS. 51A and 51B depict a system 5100 including a base module and at least one sensor module (sensor device 5102) that can be used in an experiment involving tension and optionally pendulum motion, in accordance with certain embodiments of the present disclosure. In this example, the sensor device 5102 may be coupled to a string or tether 5104 from which the sensor device 5102 can hang and optionally swing. The sensor device 5102 may also be coupled to a mass 5106.

In the example of FIG. 51B, the system 5110 includes the sensor device 5102, which is shown to include a base module 102 coupled to a sensor module 104. The sensor module 104 may include one or more detachable hooks to facilitate attachment and optionally measurement of tension. Other embodiments are also possible.

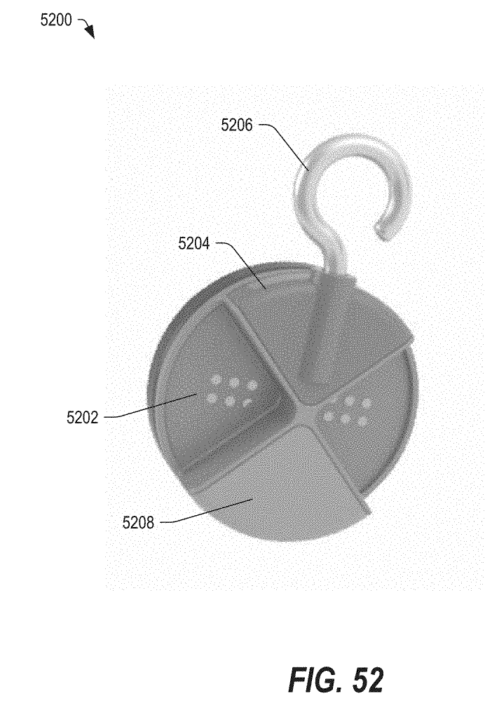

FIG. 52 depicts a sensor device 5200 including a base module 5202 and a plurality of sensor modules 5204 and 5208, in accordance with certain embodiments of the present disclosure. In this example, the base module 5202 may include a substantially cylindrical shape and may include a plurality of wedge-shaped sensor interfaces, which may be configured to couple to and engage with wedge-shaped sensor elements 5204 and 5208. In this example, the sensor element 5204 may include a hook 5206, which may be coupled to a string or to another element. In this example, the wedge-shaped sensor elements 5204 and 5208 may be coupled mechanically, magnetically, electrically, or any combination thereof to the base module 5202.

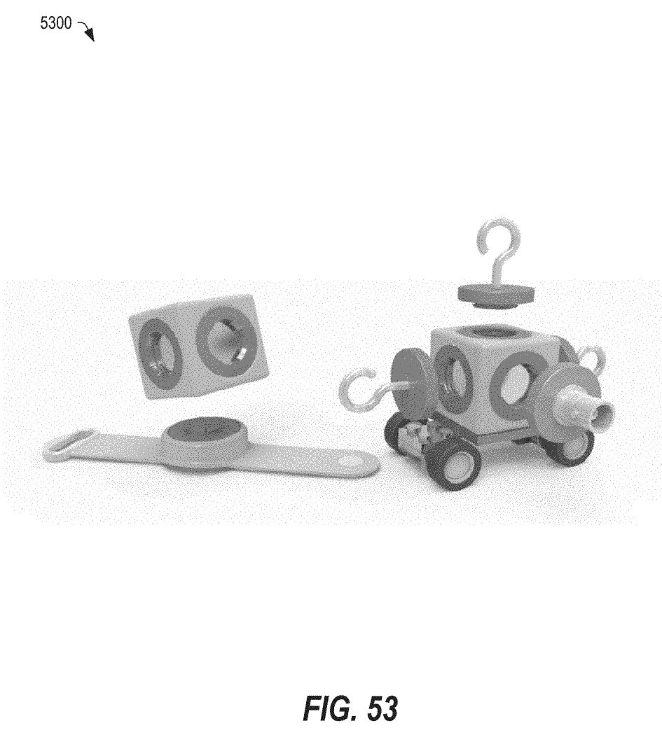

FIG. 53 depicts sensor devices 5300 including a base module and a plurality of sensor modules having a twist and lock attachment feature, in accordance with certain embodiments of the present disclosure. The sensor devices may be coupled to a wearable element, such as a wrist band. In some embodiments, the sensor devices may be coupled to a cart or to another device.

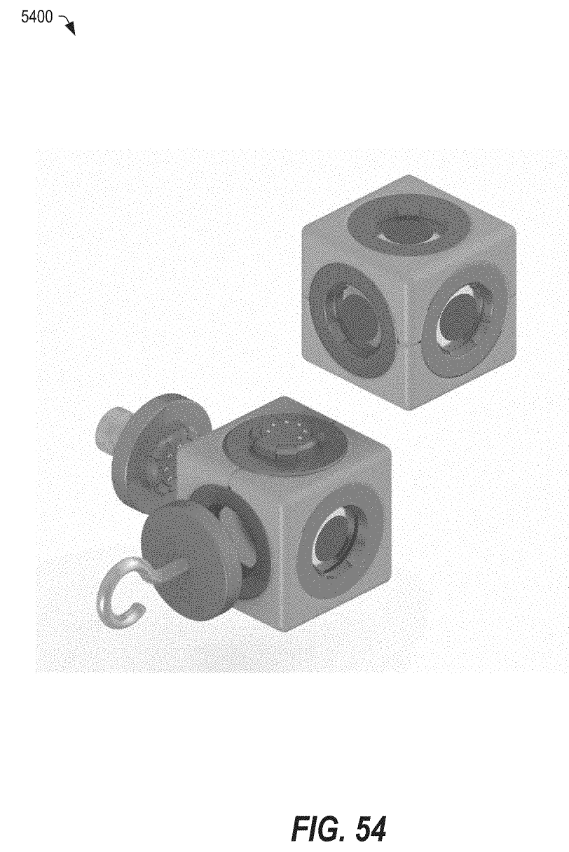

FIG. 54 depicts sensor devices 5400 including a base module and a plurality of sensor modules having a twist and lock attachment feature, in accordance with certain embodiments of the present disclosure. The sensor devices may be coupled to a wearable element, such as a wrist band. In some embodiments, the sensor devices may be coupled to a cart or to another device.

In conjunction with the systems, modules, circuits, and methods described above with respect to FIGS. 1-54, a modular system is disclosed that includes a data transmitter/collector module (i.e., a base module 102) and one or more measuring devices/sensors (i.e., a sensor module 104), which may be stacked on one another and on the base module to form a sensor device. The sensor devices may be coupled magnetically, mechanically, electrically, or any combination thereof. Further, the base module 102 may include a rechargeable battery, which may be recharged inductively using an inductive recharger or which may be recharged using a micro USB connection. Further, one or more base modules and one or more sensor modules may be coupled together to provide a desired functionality.

The modularity of product lowers the price of the suite, since the same transmission module can be used with all available sensors, especially since the transmitter is expected to be the most costly. Further, by separating the sensor from the communication module, the communication module can be made to support multiple sensors and multiple communication protocols, such that the base module 102 may be configurable to communicate with one or more sensors (simultaneously or substantially concurrently) and to communicate data from the one or more sensors to the computing device. In some embodiments, the sensor modules may stack one to another and to a base module to form a sensor device. Selection of one or more sensors may configure the device to provide a multi-sensor function. One or more sensors may communicate wirelessly with the base module. Further, the base module may communicate with a computing device through a wired or wireless communication link. In some embodiments, the raw data may be processed by the computing device. In other embodiments, the raw data may be processed by an analytics module accessible through a network, and the processed data may be sent to the computing device for review, display, and optionally further processing.

The modular design can outperform existing sensor devices in terms of price and versatility. Further, the modular design allows for wireless communications and mixed-mode communications that can allow for more flexibility when it comes to designing experiments. The sensor modules may be configured to measure a wide range of parameters, including acceleration, temperature, pressure, humidity, PH, distance, magnetic field, and so on. Further, the modular design allows for different ways of data collection via a micro USB cables, short-range wireless, memory devices, other mechanisms, or any combination thereof.

The software may enable users to collect data on their computer or smartphones and tablets. The data can be saved in commonly utilized file formats, such as the portable document format (PDF), a spreadsheet format, a text format, an image format, or any combination thereof. In some embodiments, the data may be stored in a flat file or in a database structure.

The illustrations, examples, and embodiments described herein are intended to provide a general understanding of the structure of various embodiments. The illustrations are not intended to serve as a complete description of all of the elements and features of apparatus and systems that utilize the structures or methods described herein. Many other embodiments may be apparent to those of skill in the art upon reviewing the disclosure. Other embodiments may be utilized and derived from the disclosure, such that structural and logical substitutions and changes may be made without departing from the scope of the disclosure. For example, in the flow diagrams presented herein, in certain embodiments, blocks may be removed or combined without departing from the scope of the disclosure. Further, structural and functional elements within the diagram may be combined, in certain embodiments, without departing from the scope of the disclosure. Moreover, although specific embodiments have been illustrated and described herein, it should be appreciated that any subsequent arrangement designed to achieve the same or similar purpose may be substituted for the specific embodiments shown.

This disclosure is intended to cover any and all subsequent adaptations or variations of various embodiments. Combinations of the examples, and other embodiments not specifically described herein, will be apparent to those of skill in the art upon reviewing the description. Additionally, the illustrations are merely representational and may not be drawn to scale. Certain proportions within the illustrations may be exaggerated, while other proportions may be reduced. Accordingly, the disclosure and the figures are to be regarded as illustrative and not restrictive.

What is claimed is:

1. A sensor device comprising:
a base module including a battery and including a transceiver configured to communicate with a computing device; and
one or more sensor modules configured to releasably couple to the base module, each sensor module configured to receive power from the base module and to provide data to the base module.

2. The sensor device of claim 1, wherein the base module comprises:
at least one magnet configured to couple to a magnet of a first sensor module of the one or more sensor modules; and
an interface configured to electrically couple to the one or more sensor modules.

3. The sensor device of claim 1, wherein the interface includes a plurality of contacts, the plurality of contacts including:
at least one power supply; and
at least one communication bus.

4. The sensor device of claim 1, wherein the one or more sensor modules comprise:
a first sensor module configured to releasably connect to the base module;
at least one second sensor module configured to couple to the base module through the first sensor module.

5. The sensor device of claim 4, wherein each sensor module of the one or more sensor modules includes a first interface closest to the base module and a second interface further from the base module than the first interface, the first interface including at least one magnet and including a plurality of electrical contacts, the second interface including at least one magnet and including a plurality of electrical contacts.

6. The sensor device of claim 1, wherein the one or more sensor modules include at least one of a temperature sensor, a motion sensor, a pressure sensor, and a force sensor.

7. The sensor device of claim 1, wherein the base module further includes:
an interface coupled to a first sensor module of the one or more sensor modules;
a controller coupled to the transceiver and to the first sensor; and
at least one transducer coupled to the controller.

8. An apparatus comprising:
a sensor device including a base module including a transceiver, a sensor interface, and a power supply, the sensor device further including one or more sensor modules including a first sensor module coupled to the sensor interface of the base module to provide sensor data, the base module configured to provide data related to the sensor data to a wireless communications link via the transceiver; and
a computing device configured to receive the data from the base module via the wireless communications link, the computing device configured to display one or more visualizations based on the data.

9. The apparatus of claim 8, wherein the base module comprises:
at least one magnet; and
the sensor interface including a plurality of electrical contacts, at least one of the electrical contacts to provide power to the one or more sensor modules and at least one of the electrical contacts to receive the sensor data.

10. The apparatus of claim 9, wherein each of the one or more sensor modules comprises:
a first side; and
a second side opposite to the first side, the second side further from the base unit than the first side.

11. The apparatus of claim 10, wherein, for each of the one or more sensor modules:
the first side comprises:
at least one magnet configured to couple to the at least one magnet of the base module;
a plurality of electrical contacts configured to electrically couple to the plurality of electrical contacts of the base module; and
the second side comprises:
at least one magnet configured to selectively couple to the at least one magnet of the first side of a next sensor module of the one or more sensor modules; and
a plurality of electrical contacts configured to electrically couple to the plurality of electrical contacts of the next sensor module.

12. The apparatus of claim 11, wherein the at least one magnet of the base module and the at least one magnet of the first sensor module cooperate to orient the sensor module to the base module.

13. The apparatus of claim 8, wherein the one or more sensor modules include a plurality of sensor modules arranged in a stack.

14. A sensor device comprising:
a base module including a battery and including a transceiver configured to communicate with a computing device; and
one or more sensor modules configured to magnetically couple to the base module, each sensor module configured to receive power from the base module and to provide data to the base module.

15. The sensor device of claim 14, wherein the one or more sensor modules include at least one of an accelerometer, a gyroscope, a temperature sensor, a pressure sensor, and a force sensor.

16. The sensor device of claim 14, wherein:
the base module includes a sensor interface including at least one magnet and including a plurality of electrical contacts; and
a first sensor module of the one or more sensor modules includes at least one magnet configured to couple to the at least one magnet of the base module, the first sensor module further including a plurality of contacts configured to electrically couple to the plurality of electrical contacts of the base module.

17. The sensor device of claim 14, wherein the base module further includes:
a transducer configured to produce a signal in response to a physical parameter; and
a controller coupled to the transducer and to the transceiver, the controller configured to communicate data from the transducer and from the one or more sensor modules to the computing device.

18. The sensor device of claim 14, wherein each sensor module of the one or more modules includes:
a first side including at least one magnet and including a plurality of electrical contacts, the first side configured to couple to the base module; and
a second side including at least one magnet and including a plurality of electrical contacts, the second side configured to couple to other sensor modules of the one or more sensor modules.

19. The sensor device of claim 18, wherein the at least one magnet of the first side and the at least one magnet of the second side cooperate to orient a first sensor module of the one or more sensor modules to a second sensor module of the one or more sensor modules.

20. The sensor device of claim 14, wherein the base module is configured to send data related to the sensor data from the one or more sensor modules to the computing device.
